(19) United States
(12) Patent Application Publication
(10) Pub. No.: US 2007/0170817 A1
(43) Pub. Date: Jul. 26, 2007

(54) PIEZOELECTRIC/ELECTROSTRICTIVE DEVICE

(75) Inventors: Koji IKEDA, Tsu-City (JP); Kazuyoshi Shibata, Mizunami-City (JP); Nobuo Takahashi, Kasugai-City (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 11/624,812

(22) Filed: Jan. 19, 2007

(30) Foreign Application Priority Data
Jan. 24, 2006 (JP) 2006-015684
Apr. 21, 2006 (JP) 2006-118159

(51) Int. Cl. H01L 41/08

(52) U.S. Cl. 310/323.04

(57) ABSTRACT

A piezoelectric/electrostrictive device has a rotor substantially in the form of a rectangular parallelepiped, and a rotary actuator for angularly displacing the rotor 12. The rotary actuator includes a stationary member, a first vibratory plate and a second vibratory plate extending in one direction from opposite sides of the stationary member, a first piezoelectric/electrostrictive element for actuating the first vibratory plate, and a second piezoelectric/electrostrictive element for actuating the second vibratory plate. The rotor includes a pair of opposite surfaces, one of the surfaces having a first end secured to an end of the first vibratory plate and a second end, which is diagonally opposite to the first end, and which is secured to an end of the second vibratory plate.

### CROSS-REFERENCE TO RELATED APPLICATIONS

This application is based upon and claims the benefit of priority from Patent Applications No. 2006-015684 filed on Jan. 24, 2006 and No. 2006-118159 filed on Apr. 21, 2006, in the Japanese Patent Office, of which the contents are incorporated herein by reference.

### BACKGROUND OF THE INVENTION

1. Field of the Invention

The present invention relates to a piezoelectric/electrostrictive device having a rotor which rotates based on displacement of a piezoelectric/electrostrictive element, or to a piezoelectric/electrostrictive device for detecting angular displacement of a rotor with a piezoelectric/electrostrictive element, for use in controlling an actuator for positional control of a hard disk drive (HDD), controlling the angle of a small reflecting mirror, controlling rotation of an antenna, controlling the θ-axis of an XY stage, and controlling rotation of a manipulator.

2. Description of the Related Art

Recently, optical, magnetic recording, and precision machining fields have been in need of displacement elements, which are capable of adjusting optical path lengths and positions within a range of submicrons. The development of displacement elements, which utilize displacement based on an inverse piezoelectric effect or an electrostrictive effect caused when a voltage is applied to a piezoelectric/electrostrictive material such as a ferroelectric substance, is under way.

Conventional piezoelectric actuators are problematic in that the movable member thereof moves a small distance because the displacement of a piezoelectric/electrostrictive material as it is expanded or contracted is directly transferred to the movable member.

There has been proposed a piezoelectric/electrostrictive device having a long service life, which can be handled better, allows a component to be mounted easily on the movable member thereof, and can be fixed securely in position. For details, reference should be made to Japanese Laid-Open Patent Publication No. 2002-26411, for example. The disclosed piezoelectric/electrostrictive device permits the movable member to be displaced a large distance under a relatively low voltage applied thereto, and allows the movable member to be displaced at a high speed, i.e., at a high resonant frequency. The disclosed piezoelectric/electrostrictive device can provide a displacement element that is not susceptible to harmful vibrations, which can respond at a high speed, has high mechanical strength, can be handled better, and is highly resistant to shocks and humidity, and further, which also can provide a sensor element capable of detecting movable member vibrations with good accuracy.

If a piezoelectric/electrostrictive device is used as a two-stage actuator for positioning a magnetic head in a HDD (Hard Disk Drive), then the moment of inertia thereof is reduced, for enabling highly accurate positioning control by alignment of the center of gravity of a slider with the rotational axis of the actuator.

Most HDDs that are in use today are of a type in which the axial direction of a head/stack assembly, which is actuatable by an actuator such as a voice coil motor or the like, is close to a direction that is tangential to the tracks. When the slider located at a distal portion of the head/stack assembly of the HDD of this type moves radially with respect to a given track, the skew angle of the axial direction of the head/stack assembly with respect to the direction tangential to the track varies, or in other words, the tangential direction and the axial direction deviate from each other.

The slider supports thereon a head element for recording and reproducing data, which is pressed against the surface of the magnetic disk under spring forces of the head/stack assembly. When the magnetic disk rotates, the slider is lifted off the magnetic disk under a lifting force generated by an air stream produced by rotation of the magnetic disk, and remains spaced a small gap from the surface of the magnetic disk due to a state of balance between the pressing force acting on the slider and the lifting force applied to the slider.

When the axial direction of the head/stack assembly deviates from the direction tangential to the tracks, since the vector of the air stream changes greatly, the lifted state of the magnetic head also changes greatly, and the gap by which the magnetic head is lifted off the magnetic disk becomes unstable. As a result, it becomes difficult to stably utilize the electromagnetic conversion capability of the magnetic disk itself.

According to one solution, it has been practiced to modify the air bearing surface configuration of the slider for stabilizing the lifted state of the magnetic head. If the slider is angularly displaceable so as to keep the skew angle small, then inasmuch as the above problems do not arise, the lifted state of the magnetic head becomes stable for high operational reliability.

Perpendicular magnetic recording, in particular, tends to suffer a side write problem, depending on the configuration of the main magnetic pole. HDDs based on the principles of perpendicular magnetic recording are subject to side write/side erase problems on the main magnetic pole of the write head, particularly if the skew angle is large.

When a surface of the main magnetic pole that is parallel to the track deviates from the direction tangential to the track upon recording of data, a magnetic flux leaving from the deviating surface of the main magnetic pole interferes with an adjacent track and writes an unwanted signal in the adjacent track, tending to weaken the magnetic field of the signal originally recorded in the adjacent track, or to weaken a signal read from the adjacent track, thereby causing a readout error.

For solving the above problems, it has been proposed to employ an inversely trapezoidal main magnetic pole having a width that is greater on its trailing end and smaller on its leading end. There has also been proposed a discrete recording medium with nonmagnetic layers disposed between tracks.

However, it is very difficult to manufacture inversely trapezoidal main magnetic poles of stable dimensions and to impart highly accurate angles to such inversely trapezoidal main magnetic poles. In addition, the discrete recording medium is highly costly to manufacture.

### SUMMARY OF THE INVENTION

The present invention has been made taking the foregoing problems into consideration, it is an object of the present invention to provide a piezoelectric/electrostrictive device, which is capable of angularly displacing an object with its center of gravity moving a reduced distance, thereby reducing reactive forces generated in a region where the piezoelectric/electrostrictive device is fixed in position, so that the object can be actuated under an easy control and with an increased actuating frequency, i.e., an increased response speed.

According to a first aspect of the present invention, there is provided a piezoelectric/electrostrictive device comprising a rotor and a rotary actuator for angularly displacing the rotor, the rotary actuator having a stationary member, with a first vibratory plate and a second vibratory plate extending in one direction from opposite sides of the stationary member, and a piezoelectric/electrostrictive element mounted on at least one of the first and second vibratory plates for actuating the at least one of the first and second vibratory plates, and the rotor having a pair of opposite surfaces, one of the opposite surfaces including a first end secured to the first vibratory plate, and the other of the opposite surfaces having a second end, which is diagonally opposite to the first end, secured to the second vibratory plate.

In the first aspect of the present invention, the distance between the first end of the rotor that is secured to the first vibratory plate and a boundary region between the first vibratory plate and the stationary member is represented by L1, and the distance between the second end of the rotor that is secured to the second vibratory plate and a boundary region between the second vibratory plate and the stationary member is represented by L2, wherein the distance L1 and the distance L2 may satisfy the relationship L1=L2.

According to a second aspect of the present invention, there is provided a piezoelectric/electrostrictive device comprising a rotor and a rotary actuator for angularly displacing the rotor, the rotary actuator having a first stationary member and a second stationary member which are spaced from each other, a first vibratory plate extending in one direction from one side of the first stationary member, a second vibratory plate extending in one direction from one side of the second stationary member, and a piezoelectric/electrostrictive element mounted on at least one of the first and second vibratory plates for actuating the at least one of the first and second vibratory plates, and the rotor having a pair of opposite surfaces, one of the opposite surfaces including a first end secured to the first vibratory plate, and the other of the opposite surfaces having a second end, which is diagonally opposite to the first end, secured to the second vibratory plate.

In the second aspect of the present invention, the first vibratory plate may have a first protrusion mounted on a surface thereof which faces the one surface of the rotor, and the second vibratory plate may have a second protrusion mounted on a surface thereof which faces the other surface of the rotor, wherein the first protrusion and the one surface of the rotor are secured to each other, and the second protrusion and the other surface of the rotor are secured to each other.

In the second aspect of the present invention, the first stationary member may have a third protrusion mounted on a surface thereof which faces the rotor, and the second stationary member may have a fourth protrusion mounted on a surface thereof which faces the rotor, wherein the third protrusion and the rotor are secured to each other, and the fourth protrusion and the rotor are secured to each other.

According to a third aspect of the present invention, there is provided a piezoelectric/electrostrictive device comprising a rotor and a rotary actuator for angularly displacing the rotor, the rotary actuator having a central member extending in a first direction, a first arm extending from a first end of the central member in a second direction, a second arm extending from a second end of the central member in a third direction which is opposite to the second direction, a first vibratory plate extending from an end of the first arm in the first direction, a third arm extending from an end of the first vibratory plate in the third direction, a second vibratory plate extending from an end of the second arm in the first direction, a fourth arm extending from an end of the second vibratory plate in the second direction, and a piezoelectric/electrostrictive element mounted on at least one of the first and second vibratory plates for actuating the at least one of the first and second vibratory plates.

In the third aspect of the present invention, the central member may comprise a stationary member, and the rotor may have, on a principal surface thereof, a first corner secured to the third arm and a second corner, which is diagonally opposite to the first corner, secured to the fourth arm.

In the third aspect of the present invention, each of the third arm and the fourth arm may comprise a stationary member, wherein the rotor is secured to the central member.

According to a fourth aspect of the present invention, there is provided a piezoelectric/electrostrictive device comprising a rotor and a rotary actuator for angularly displacing the rotor, the rotary actuator having a first stationary member and a second stationary member which are spaced from each other, a central member disposed between the first stationary member and the second stationary member and extending in a first direction, a first vibratory plate extending from a first end of the first stationary member toward the second stationary member, a second vibratory plate extending from a second end, which is diagonally opposite to the first end, of the second stationary member toward the first stationary member, a first displacement transmitter connected between a third end, which is closer to the first stationary member, of the central member on a surface thereof which faces the first vibratory plate, and an end of the first vibratory plate, for transmitting displacement of the first vibratory plate to the central member, a second displacement transmitter connected between a fourth end, which is closer to the second stationary member, of the central member on a surface thereof which faces the second vibratory plate, and an end of the second vibratory plate, for transmitting displacement of the second vibratory plate to the central member, and a piezoelectric/electrostrictive element mounted on at least one of the first and second vibratory plates for actuating the at least one of the first and second vibratory plates, wherein the rotor is secured to the central member.

According to a fifth aspect of the present invention, there is provided a piezoelectric/electrostrictive device comprising a rotor and a rotary actuator for angularly displacing the rotor, the rotary actuator having a first stationary member and a second stationary member which are spaced from each other, a first metal vibratory plate extending from the first stationary member toward the second stationary member, a second metal vibratory plate extending from the second stationary member toward the first stationary member, and a piezoelectric/electrostrictive element mounted on at least one of the first and second vibratory plates for actuating the at least one of the first and second vibratory plates, and the rotor having a pair of opposite surfaces, one of the opposite surfaces having a first end secured to the first vibratory plate, and the other of the opposite surfaces having a second end, which is diagonally opposite to the first end, secured to the second vibratory plate.

In the fifth aspect of the present invention, the first stationary member and the second stationary member may be integrally combined with each other by a frame.

In the fifth aspect of the present invention, the first stationary member, the first vibratory plate, the second stationary member, and the second vibratory plate may be formed by punching and bending a single metal plate.

According to a sixth aspect of the present invention, there is provided a piezoelectric/electrostrictive device comprising a rotor and a rotary actuator for angularly displacing the rotor, the rotary actuator having a first stationary member and a second stationary member which are spaced from each other, a first metal vibratory plate extending from the first stationary member toward the second stationary member, a second metal vibratory plate extending from the second stationary member toward the first stationary member, a rotor mount secured to an end of the first vibratory plate and to an end of the second vibratory plate, and a piezoelectric/electrostrictive element mounted on at least one of the first and second vibratory plates for actuating the at least one of the first and second vibratory plates, wherein the rotor is mounted on the rotor mount.

In the sixth aspect of the present invention, the first stationary member and the second stationary member may be integrally combined with each other by a frame.

In the sixth aspect of the present invention, the first stationary member, the first vibratory plate, the second stationary member, the second vibratory plate, and the rotor mount may be formed by punching and bending a single metal plate.

According to a seventh aspect of the present invention, there is provided a piezoelectric/electrostrictive device comprising a rotor and a rotary actuator for angularly displacing the rotor, the rotary actuator having a stationary member, a first metal vibratory plate having an end secured to the stationary member and extending in one direction, a second metal vibratory plate having an end secured to the stationary member and extending along an extension of the first vibratory plate, a third metal vibratory plate having an end secured to the stationary member, the third vibratory plate being spaced from the first vibratory plate and extending substantially parallel thereto, a fourth metal vibratory plate having an end secured to the stationary member and extending along an extension of the third vibratory plate, and a piezoelectric/electrostrictive element mounted on at least one of the first through fourth vibratory plates for actuating the at least one of the first through fourth vibratory plates, and the rotor having a pair of opposite surfaces, one of the opposite surfaces having a first end secured to the first vibratory plate, and the other of the opposite surfaces having a second end, which is diagonally opposite to the first end, secured to the fourth vibratory plate.

In the seventh aspect of the present invention, the stationary member may comprise a frame, the first vibratory plate and the second vibratory plate may be secured to a first arm extending from one of two opposite surfaces of the frame to the other surface thereof, and the third vibratory plate and the fourth vibratory plate may be secured to a second arm extending from the other surface of the frame to the one surface thereof.

In the seventh aspect of the present invention, the stationary member may have a rectangular planar shape, the first vibratory plate and the second vibratory plate may be secured to a first arm extending upwardly from one of two opposite surfaces of the stationary member, and the third vibratory plate and the fourth vibratory plate may be secured to a second arm extending upwardly from the other of the two opposite surfaces of the stationary member.

In the seventh aspect of the present invention, the stationary member and the first through fourth vibratory plates may be formed by punching and bending a single metal plate.

In the seventh aspect of the present invention, those of the first through fourth vibratory plates which are free of the piezoelectric/electrostrictive element may comprise a spring.

According to an eighth aspect of the present invention, there is provided a piezoelectric/electrostrictive device comprising a rotor and a rotary actuator for angularly displacing the rotor, the rotary actuator having a stationary member, a first metal vibratory plate having an end secured to the stationary member and extending in one direction, a second metal vibratory plate having an end secured to the stationary member and extending along an extension of the first vibratory plate, a third metal vibratory plate having an end secured to the stationary member, the third vibratory plate being spaced from the first vibratory plate and extending substantially parallel thereto, a fourth metal vibratory plate having an end secured to the stationary member and extending along an extension of the third vibratory plate, a rotor mount secured to respective ends of the first through fourth vibratory plates, and a piezoelectric/electrostrictive element mounted on at least one of the first through fourth vibratory plates for actuating the at least one of the first through fourth vibratory plates, wherein the rotor is mounted on the rotor mount.

In the eighth aspect of the present invention, the stationary member may comprise a frame, wherein the first vibratory plate and the second vibratory plate are secured to a first arm extending from one of two opposite surfaces of the frame to the other surface thereof, and the third vibratory plate and the fourth vibratory plate are secured to a second arm extending from the other surface of the frame to the one surface thereof.

In the eighth aspect of the present invention, the stationary member may have a rectangular planar shape, wherein the first vibratory plate and the second vibratory plate are secured to a first arm extending upwardly from one of two opposite surfaces of the stationary member, and the third vibratory plate and the fourth vibratory plate are secured to a second arm extending upwardly from the other of the two opposite surfaces of the stationary member.

In the eighth aspect of the present invention, the rotor mount may comprise a plurality of feet fixed to respective ends of the first through fourth vibratory plates.

In the eighth aspect of the present invention, the stationary member, the first through fourth vibratory plates, and the rotor mount may be formed by punching and bending a single metal plate.

In the eighth aspect of the present invention, those of the first through fourth vibratory plates which are free of the piezoelectric/electrostrictive element may comprise a spring.

According to a ninth aspect of the present invention, there is provided a piezoelectric/electrostrictive device comprising a rotor and a rotary actuator for angularly displacing the rotor, the rotary actuator having a stationary member, a first vibratory plate and a second vibratory plate which have respective ends secured to the stationary member and are angularly spaced from each other by a predetermined angle, a movable member connected between the other end of the first vibratory plate and the other end of the second vibratory plate, and a piezoelectric/electrostrictive element mounted on at least one of the first and second vibratory plates for actuating the at least one of the first and second vibratory plates, wherein the rotor is secured to the movable member.

In the ninth aspect of the present invention, the predetermined angle may comprise an acute angle or an obtuse angle. Further, the predetermined angle may be 90 degrees or 180 degrees.

According to a tenth aspect of the present invention, there is provided a piezoelectric/electrostrictive device comprising a rotor and a rotary actuator for angularly displacing the rotor, the rotary actuator having a stationary member, with a first vibratory plate and a second vibratory plate extending in one direction from opposite sides of the stationary member, and a piezoelectric/electrostrictive element mounted on at least one of the first and second vibratory plates for actuating the at least one of the first and second vibratory plates, and the rotor having a first connector extending from a first portion thereof, which faces the first vibratory plate, to the first vibratory plate, the first connector interconnecting the first portion and the first vibratory plate, and a second connector extending from a second portion thereof, which faces the first vibratory plate, to the second vibratory plate, the second connector interconnecting the second portion and the second vibratory plate.

In the tenth aspect of the present invention, the rotor may have a constricted portion, wherein the first portion is positioned on the constricted portion, which faces the first vibratory plate, and the second portion is positioned on the constricted portion, which faces the second vibratory plate.

In the tenth aspect of the present invention, the first connector may be of a shape having a cross-sectional area that is substantially uniform from the constricted portion to the first vibratory plate, and the second connector may be of a shape having a cross-sectional area that is substantially uniform from the constricted portion to the second vibratory plate.

In the tenth aspect of the present invention, the first connector may be of a shape having a cross-sectional area that progressively varies from the constricted portion to the first vibratory plate, and the second connector may be of a shape having a cross-sectional area that progressively varies from the constricted portion to the second vibratory plate.

In the tenth aspect of the present invention, the first connector and the first vibratory plate may be secured to each other by an adhesive, and the second connector and the second vibratory plate may be secured to each other by an adhesive.

In the tenth aspect of the present invention, the first connector and the second connector may be formed integrally with the rotor, the first vibratory plate, and the second vibratory plate by punching and bending a metal plate.

In the tenth aspect of the present invention, a first joint position between the first connector and the first vibratory plate, and a second joint position between the second connector and the second vibratory plate, may be in a substantially confronting positional relationship.

In the tenth aspect of the present invention, a third joint position between the first portion of the rotor and the first connector, and a fourth joint position between the second portion of the rotor and the second connector, may be positionally related to each other in point symmetry with respect to a center of gravity of the rotor.

According to the first through tenth aspects of the present invention, the rotor sandwiched by the vibratory plates, or the rotor mounted on the rotor mount to which the vibratory plates are secured, or the rotor secured to the movable member to which the vibratory plates are secured, is angularly displaced when the vibratory plates are actuated by the piezoelectric/electrostrictive element. When the rotor is angularly displaced in this manner, the center of gravity of the rotor essentially is not moved.

When the rotor or an object to which the rotor is fixed is angularly displaced, because movement of the center of gravity of the rotor is small, reactive forces generated in a region at which the piezoelectric/electrostrictive device is fixed in place are small, so that the piezoelectric/electrostrictive device can actuate the object under an easy control with an increased actuating frequency and an increased response speed.

Therefore, the rotor can be controlled with high accuracy when it is angularly displaced. The piezoelectric/electrostrictive device is thus suitable for use in controlling an actuator for positional control of a hard disk drive (HDD). Additionally, the piezoelectric/electrostrictive device may be used successfully for controlling the angle of a small reflecting mirror, controlling the rotation of an antenna, controlling the θ-axis of an XY stage, or controlling the rotation of a manipulator.

Particularly, if the piezoelectric/electrostrictive device is used as an actuator for positioning the magnetic head of an HDD, then the slider can be angularly displaced with high accuracy, making it possible to eliminate or reduce the skew angle. Limitations on the configuration of the pole of the head are lessened for enabling greater freedom of design. Furthermore, inasmuch as interference with adjacent tracks is avoided, gaps, which typically have been provided in view of such interference, are unnecessary and the density of the tracks can be increased. Since the formation of side shields and inversely trapezoidal shapes is facilitated or made unnecessary, the piezoelectric/electrostrictive device for use as an actuator can be manufactured at a reduced cost.

Since the rotor can be translated at a constant skew angle, functions for performing track positioning and skew angle positioning can be realized by a single actuator. The HDD can thus be designed for higher performance and further be reduced in size.

As described above, the piezoelectric/electrostrictive device according to the present invention is capable of angularly displacing an object to which the rotor is secured. When the object is angularly displaced, any movement of the center of gravity of the rotor is small, and reactive forces generated in a region at which the piezoelectric/electrostrictive device is fixed in place are small. Thus, the piezoelectric/electrostrictive device can actuate the object under an easy control with an increased actuating frequency and an increased response speed.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1 is a view showing a first piezoelectric/electrostrictive device according to the present invention;

FIG. 2 is a view showing a second piezoelectric/electrostrictive device according to the present invention;

FIG. 3 is a view showing a first modification of the first piezoelectric/electrostrictive device;

FIG. 4 is a view showing a third piezoelectric/electrostrictive device according to the present invention;

FIG. 5 is a view showing a manner in which the third piezoelectric/electrostrictive device operates according to a first process;

FIG. 6 is a view showing a manner in which the third piezoelectric/electrostrictive device operates according to a second process;

FIG. 7 is a view showing a fourth piezoelectric/electrostrictive device according to the present invention;

FIG. 8 is a plan view of a first ceramic substrate of the fourth piezoelectric/electrostrictive device;

FIG. 9 is a plan view of a second ceramic substrate of the fourth piezoelectric/electrostrictive device;

FIG. 10 is a plan view of a third ceramic substrate of the fourth piezoelectric/electrostrictive device;

FIG. 11 is a view showing a fifth piezoelectric/electrostrictive device according to the present invention;

FIG. 12 is a view showing a manner in which the fifth piezoelectric/electrostrictive device operates in a first mode;

FIG. 13 is a view showing a manner in which the fifth piezoelectric/electrostrictive device operates in a second mode;

FIG. 14 is a view showing a first modification of the fifth piezoelectric/electrostrictive device;

FIG. 15 is a view showing a step (punching step) for manufacturing the fifth piezoelectric/electrostrictive device;

FIG. 16 is a view showing a step (bending step) for manufacturing the fifth piezoelectric/electrostrictive device;

FIG. 17 is a view showing a sixth piezoelectric/electrostrictive device according to the present invention;

FIG. 18 is a view showing a manner in which the sixth piezoelectric/electrostrictive device operates;

FIG. 19 is a view showing a step (punching step) for manufacturing the sixth piezoelectric/electrostrictive device;

FIG. 20 is a view showing a step (bending step) for manufacturing the sixth piezoelectric/electrostrictive device;

FIG. 21 is a view showing a first modification of the sixth piezoelectric/electrostrictive device;

FIG. 22 is a view showing a second modification of the sixth piezoelectric/electrostrictive device;

FIG. 23 is a perspective view showing the sixth piezoelectric/electrostrictive device with a rotor fixed to a rotary actuator;

FIG. 24 is a view showing a step (punching step) for manufacturing the second modification of the sixth piezoelectric/electrostrictive device;

FIG. 25 is a view showing a step (bending step) for manufacturing the second modification of the sixth piezoelectric/electrostrictive device;

FIG. 26 is a perspective view of a seventh piezoelectric/electrostrictive device according to the present invention;

FIG. 27 is a plan view of a first modification of the seventh piezoelectric/electrostrictive device;

FIG. 28 is a plan view of a second modification of the seventh piezoelectric/electrostrictive device;

FIG. 29 is a plan view of a third modification of the seventh piezoelectric/electrostrictive device;

FIG. 30 is a plan view of a fourth modification of the seventh piezoelectric/electrostrictive device;

FIG. 31 is a plan view of a fifth modification of the seventh piezoelectric/electrostrictive device;

FIG. 32 is a view showing an eighth piezoelectric/electrostrictive device according to the present invention;

FIG. 33 is a view of a first modification of the eighth piezoelectric/electrostrictive device;

FIG. 34 is a view of a second modification of the eighth piezoelectric/electrostrictive device;

FIG. 35 is a view showing a ninth piezoelectric/electrostrictive device according to the present invention;

FIG. 36 is a view showing a tenth piezoelectric/electrostrictive device according to the present invention;

FIG. 37 is a view of a first modification of the tenth piezoelectric/electrostrictive device;

FIG. 38 is a view of a second modification of the tenth piezoelectric/electrostrictive device;

FIG. 39 is a view showing a step (punching step) for manufacturing the second modification of the tenth piezoelectric/electrostrictive device;

FIG. 40 is a view showing a step (rotary actuator fabricating step) for manufacturing the second modification of the tenth piezoelectric/electrostrictive device;

FIG. 41 is a view showing a step (adhesive applying step) for manufacturing the second modification of the tenth piezoelectric/electrostrictive device;

FIG. 42 is a view showing a step (assembling step) for manufacturing the second modification of the tenth piezoelectric/electrostrictive device;

FIG. 43 is a view showing a step (adhesive applying step) for manufacturing the second modification of the tenth piezoelectric/electrostrictive device;

FIG. 44 is a view showing a step (parts mounting step) for manufacturing the second modification of the tenth piezoelectric/electrostrictive device;

FIG. 45 is a view showing another step used in manufacturing the second modification of the tenth piezoelectric/electrostrictive device;

FIG. 46 is a view showing an eleventh piezoelectric/electrostrictive device according to the present invention; and

FIG. 47 is a view showing a modification of the eleventh piezoelectric/electrostrictive device.

### DESCRIPTION OF THE PREFERRED EMBODIMENTS

In the following descriptions, like or corresponding parts are denoted using like or corresponding reference characters throughout the views.

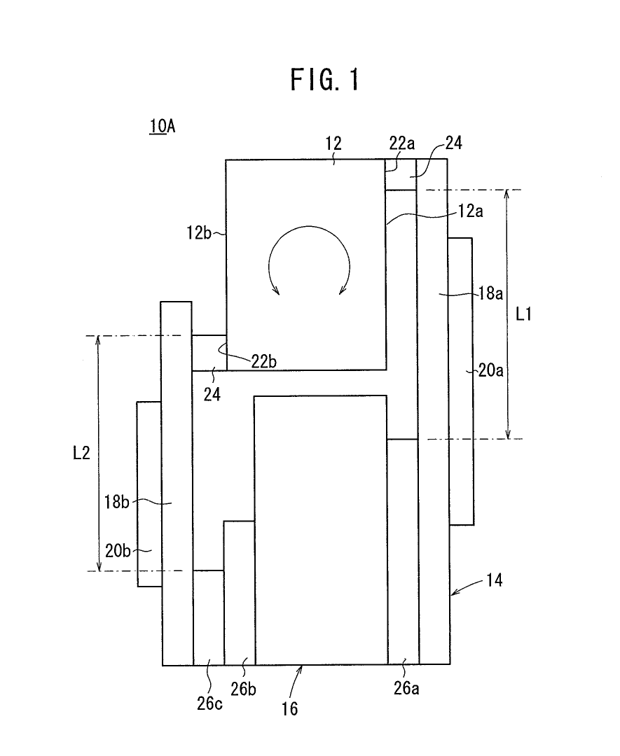

Piezoelectric/electrostrictive devices according to various embodiments of the present invention shall be described below with reference to FIGS. 1 through 47.

The concept of the piezoelectric/electrostrictive device according to the present embodiment covers devices for converting electric energy into mechanical energy and vice versa using a piezoelectric/electrostrictive element. Therefore, the piezoelectric/electrostrictive device can be used most preferably in connection with active devices, such as actuators, vibrators, etc., particularly as displacement devices utilizing displacements based on an inverse piezoelectric effect or an electrostrictive effect. The piezoelectric/electrostrictive device can also preferably be used in connection with passive devices, such as acceleration sensor devices, impact sensor devices, etc.

As shown in FIG. 1, a piezoelectric/electrostrictive device 10A according to a first embodiment of the present invention (hereinafter referred to as a first piezoelectric/electrostrictive device 10A) comprises a rotor 12 substantially in the form of a rectangular parallelepiped, the rotor 12 having a pair of opposite surfaces 12a, 12b, and a rotary actuator 14 for angularly displacing the rotor 12. A slider, a sensor, a stage, or the like may be mounted on the rotor 12. Alternatively, the rotor 12 itself may serve as a slider, a stage, or the like.

The rotary actuator 14 includes a stationary member 16, a first vibratory plate 18a and a second vibratory plate 18b extending in one direction from opposite sides of the stationary member 16, a first piezoelectric/electrostrictive element 20a mounted on and extending from a side surface of the first vibratory plate 18a to the stationary member 16 for actuating the first vibratory plate 18a, and a second piezoelectric/electrostrictive element 20b mounted on and extending from a side surface of the second vibratory plate 18b to the stationary member 16 for actuating the second vibratory plate 18b.

Of the opposite surfaces 12a, 12b of the rotor 12, the surface 12a has a first end 22a secured to an end of the first vibratory plate 18a by an adhesive 24, for example. The other surface 12b has a second end 22b, which is diagonally opposite to the first end 22a, secured to an end of the second vibratory plate 18b by an adhesive 24, for example. Therefore, the length of the second vibratory plate 18b is smaller than the length of the first vibratory plate 18a. The adhesive 24 may comprise an ultraviolet-curable resin, an epoxy resin, or the like.

A first plate member 26a used for positioning is interposed between the stationary member 16 and the first vibratory plate 18a, and a second plate member 26b and a third plate member 26c, also used for positioning, are interposed between the stationary member 16 and the second vibratory plate 18b.

When the first piezoelectric/electrostrictive element 20a actuates the first vibratory plate 18a so as to curve outwardly, in a direction to bring the end of the first vibratory plate 18a away from the end of the second vibratory plate 18b, and when the second piezoelectric/electrostrictive element 20b actuates the second vibratory plate 18b so as to curve outwardly, in a direction to bring the end of the second vibratory plate 18b away from the end of the first vibratory plate 18a, the rotor 12 is displaced angularly clockwise in FIG. 1.

Conversely, when the first piezoelectric/electrostrictive element 20a actuates the first vibratory plate 18a so as to curve inwardly, in a direction to bring the end of the first vibratory plate 18a toward the end of the second vibratory plate 18b, and when the second piezoelectric/electrostrictive element 20b actuates the second vibratory plate 18b so as to curve inwardly, in a direction to bring the end of the second vibratory plate 18b toward the end of the first vibratory plate 18a, the rotor 12 is displaced angularly counterclockwise in FIG. 1.

It is assumed that the distance between the first end 22a of the rotor 12 that is secured to the first vibratory plate 18a and the boundary region between the first vibratory plate 18a and the stationary member 16 is represented by L1, and the distance between the second end 22b of the rotor 12 that is secured to the second vibratory plate 18b and the boundary region between the second vibratory plate 18b and the stationary member 16 is represented by L2. Angular displacement of the rotor 12 is increased if L1=L2.

When the first piezoelectric/electrostrictive element 20a actuates the first vibratory plate 18a so as to curve outwardly, and the second piezoelectric/electrostrictive element 20b actuates the second vibratory plate 18b so as to curve inwardly, the rotor 12 is translated to the right in FIG. 1. When the first piezoelectric/electrostrictive element 20a actuates the first vibratory plate 18a so as to curve inwardly, and the second piezoelectric/electrostrictive element 20b actuates the second vibratory plate 18b so as to curve outwardly, the rotor 12 is translated to the left in FIG. 1.

The stationary member 16, the first vibratory plate 18a, the second vibratory plate 18b, and the first through third plate members 26a through 26c may comprise an integrally sintered assembly of laminated ceramic green sheets. The first piezoelectric/electrostrictive element 20a and the second piezoelectric/electrostrictive element 20b may be formed by screen printing, on respective side surfaces of the first vibratory plate 18a and the second vibratory plate 18b. The first vibratory plate 18a and the second vibratory plate 18b may alternatively be made of metal. If the first vibratory plate 18a and the second vibratory plate 18b are made of metal, then the first piezoelectric/electrostrictive element 20a and the second piezoelectric/electrostrictive element 20b are secured to respective side surfaces of the first vibratory plate 18a and the second vibratory plate 18b by an adhesive, for example.

With the first piezoelectric/electrostrictive device 10A, therefore, the first vibratory plate 18a and the second vibratory plate 18b sandwich the rotor 12 therebetween, and are actuated respectively by the first piezoelectric/electrostrictive element 20a and the second piezoelectric/electrostrictive element 20b in order to angularly displace the rotor 21.

In this case where the rotor 12 is sandwiched by the first vibratory plate 18a and the second vibratory plate 18b, since the first end 22a of one surface 12a of the rotor 12 is fixed to the end of the first vibratory plate 18a, and the second end 22b, which is diagonally opposite to the first end 22a, of the other surface 12b of the rotor 12 is fixed to the end of the second vibratory plate 18b, the center of gravity of the rotor 12 essentially is not moved when the rotor 12 is angularly displaced.

When the rotor 12, or an object to which the rotor 12 is fixed, is angularly displaced, because movement of the center of gravity of the rotor 12 is small, reactive forces generated in a region (i.e., the region of the stationary member 16) at which the first piezoelectric/electrostrictive device 10A is fixed in place are small, the first piezoelectric/electrostrictive device 10A can actuate the object under an easy control with an increased actuating frequency and an increased response speed.

Therefore, the rotor 12 can be controlled with high accuracy when it is angularly displaced. The first piezoelectric/electrostrictive device 10A is thus suitable for use in controlling an actuator for positional control of a hard disk drive (HDD), as well as for controlling the angle of a small reflecting mirror, controlling the rotation of an antenna, controlling the θ-axis of an XY stage, or controlling the rotation of a manipulator.

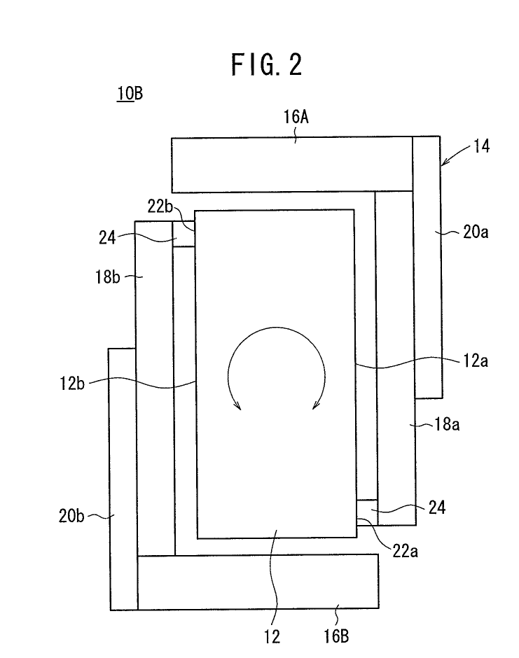

A piezoelectric/electrostrictive device 10B according to a second embodiment (hereinafter referred to as a second piezoelectric/electrostrictive device 10B) of the present invention shall be described below with reference to FIG. 2.

As shown in FIG. 2, the second piezoelectric/electrostrictive device 10B comprises a rotor 12 substantially in the form of a rectangular parallelepiped, the rotor 12 having a pair of opposite surfaces 12a, 12b, and a rotary actuator 14 for angularly displacing the rotor 12.

The rotary actuator 14 includes a first stationary member 16A and a second stationary member 16B, which are spaced from each other, a first vibratory plate 18a extending in one direction from one side of the first stationary member 16A, a second vibratory plate 18b extending in one direction from one side of the second stationary member 16B, a first piezoelectric/electrostrictive element 20a mounted on and extending from a side surface of the first vibratory plate 18a to the first stationary member 16A for actuating the first vibratory plate 18a, and a second piezoelectric/electrostrictive element 20b mounted on and extending from a side surface of the second vibratory plate 18b to the second stationary member 16B for actuating the second vibratory plate 18b.

Of the opposite surfaces 12a, 12b of the rotor 12, the surface 12a has a first end 22a secured to an end of the first vibratory plate 18a by an adhesive 24, for example. The other surface 12b has a second end 22b, which is diagonally opposite to the first end 22a, secured to an end of the second vibratory plate 18b by an adhesive 24, for example.

When the first piezoelectric/electrostrictive element 20a actuates the first vibratory plate 18a so as to curve outwardly, and the second piezoelectric/electrostrictive element 20b actuates the second vibratory plate 18b so as to curve outwardly, the rotor 12 is angularly moved counterclockwise in FIG. 2.

Conversely, when the first piezoelectric/electrostrictive element 20a actuates the first vibratory plate 18a so as to curve inwardly, and the second piezoelectric/electrostrictive element 20b actuates the second vibratory plate 18b so as to curve inwardly, the rotor 12 is angularly moved clockwise in FIG. 2.

In the second piezoelectric/electrostrictive device 10B, as with the first piezoelectric/electrostrictive device 10A, therefore, when the rotor 12 and an object to which the rotor 12 is connected are angularly displaced, any movement of the center of gravity of the rotor 12 is small. Therefore, reactive forces generated within a region (i.e., a region of the first stationary member 16A and the second stationary member 16B) at which the second piezoelectric/electrostrictive device 10B is fixed in place are small, and hence the second piezoelectric/electrostrictive device 10B can actuate the rotor 12 and the object under an easy control with an increased actuating frequency and an increased response speed.

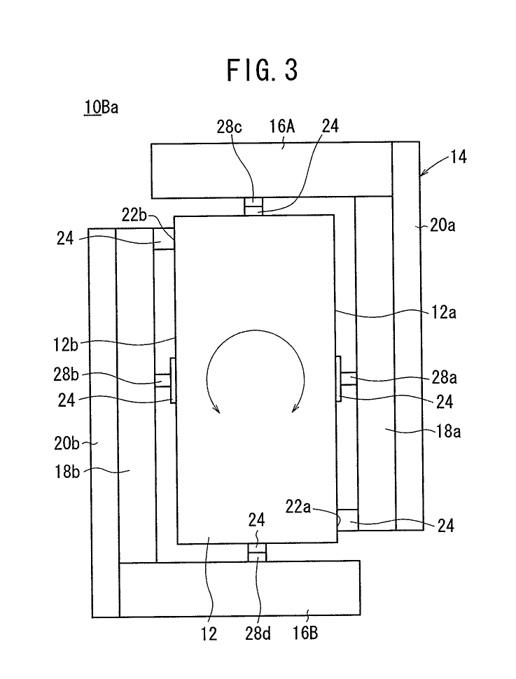

In the second embodiment shown in FIG. 2, the rotary actuator 14 is fixed to the rotor 12 at two locations. FIG. 3 shows a modified piezoelectric/electrostrictive device 10Ba. In FIG. 3, the first vibratory plate 18a has a first protrusion 28a mounted on a surface thereof which faces one surface 12a of the rotor 12 at a longitudinally central position, and the second vibratory plate 18b has a second protrusion 28b mounted on a surface thereof which faces another surface 12b of the rotor 12 at a longitudinally central position. The protrusion 28a is bonded to the one surface 12a of the rotor 12 by an adhesive 24, and the protrusion 28b is bonded to the other surface 12b of the rotor 12 by an adhesive 24.

The first stationary member 16A has a third protrusion 28c mounted on a surface thereof which faces the rotor 12 at a longitudinally central position thereof, and the second stationary member 16B has a fourth protrusion 28d mounted on a surface thereof which faces the rotor 12 at a longitudinally central position thereof. The third protrusion 28c is bonded to the rotor 12 by an adhesive 24, and the fourth protrusion 28d also is bonded to the rotor 12 by an adhesive 24.

The modified piezoelectric/electrostrictive device 10Ba shown in FIG. 3 is effective to prevent the rotor 12 from being torsionally and transversely displaced, and to cause the rotor 12 to be only angularly displaced.

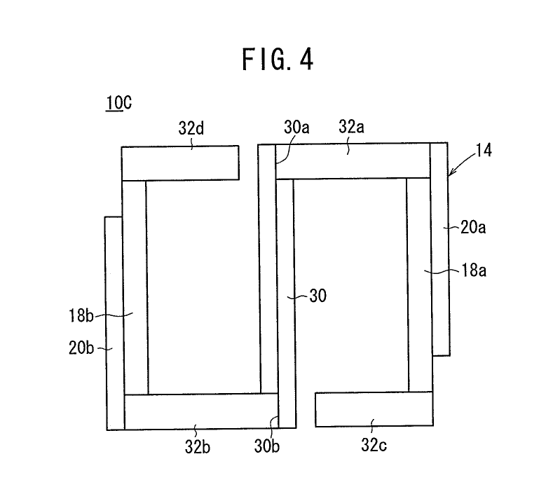

A piezoelectric/electrostrictive device 10C according to a third embodiment (hereinafter referred to as a third piezoelectric/electrostrictive device 10C) of the present invention shall be described below with reference to FIG. 4.

As shown in FIG. 4, the third piezoelectric/electrostrictive device 10C comprises a rotor 12 (not shown in FIG. 4) substantially in the form of a rectangular parallelepiped, and a rotary actuator 14 for angularly displacing the rotor 12.

The rotary actuator 14 includes a central member 30 extending in a first direction, a first arm 32a extending from a first end 30a of the central member 30 in a second direction, a second arm 32b extending from a second end 30b of the central member 30 in a third direction that is opposite to the second direction, a first vibratory plate 18a extending from an end of the first arm 32a in the first direction, a third arm 32c extending from an end of the first vibratory plate 18a in the third direction, a second vibratory plate 18b extending from an end of the second arm 32b in the first direction, a fourth arm 32d extending from an end of the second vibratory plate 18b in the second direction, a first piezoelectric/electrostrictive element 20a mounted on at least one side surface of the first vibratory plate 18a for actuating the first vibratory plate 18a, and a second piezoelectric/electrostrictive element 20b mounted on at least one side surface of the second vibratory plate 18b for actuating the second vibratory plate 18b.

The third piezoelectric/electrostrictive device 10C can be used according to at least two processes.

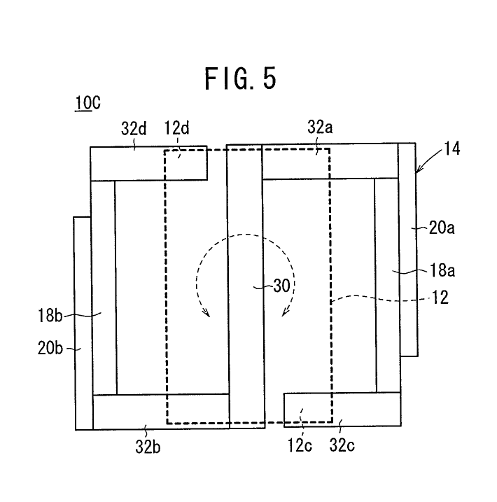

According to a first process, as shown in FIG. 5, the central member 30 is used as a stationary member, wherein the rotor 12 has a first corner 12c on its principal surface, which is secured to the third arm 32c by an adhesive, for example. Also, the rotor 12 has a second corner 12d on its principal surface, which is diagonally opposite to the first corner 12c, and which is secured to the fourth arm 32d by an adhesive, for example. The first piezoelectric/electrostrictive element 20a is mounted on and extends from a side surface of the first vibratory plate 18a to the first arm 32a, and the second piezoelectric/electrostrictive element 20b is mounted on and extends from a side surface of the second vibratory plate 18b to the second arm 32b.

When the first piezoelectric/electrostrictive element 20a actuates the first vibratory plate 18a so as to curve outwardly in a direction to bring the end of the third arm 32c away from the central member 30, and the second piezoelectric/electrostrictive element 20b actuates the second vibratory plate 18b so as to curve outwardly in a direction to bring the end of the fourth arm 32d away from the central member 30, the rotor 12 is angularly displaced counterclockwise in FIG. 5.

Conversely, when the first piezoelectric/electrostrictive element 20a actuates the first vibratory plate 18a so as to curve inwardly in a direction to bring the end of the third arm 32c toward the central member 30, and the second piezoelectric/electrostrictive element 20b actuates the second vibratory plate 18b so as to curve inwardly in a direction to bring the end of the fourth arm 32d toward the central member 30, the rotor 12 is angularly displaced clockwise in FIG. 5.

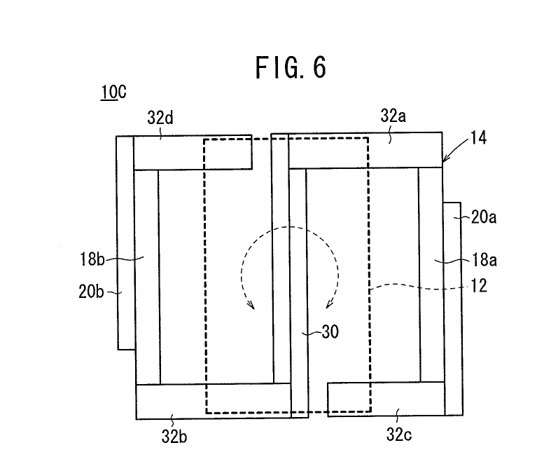

According to a second process, as shown in FIG. 6, the third arm 32c and the fourth arm 32d are used as stationary members, and the rotor 12 is secured to the central member 30 by an adhesive, for example. The first piezoelectric/electrostrictive element 20a is mounted on and extends from a side surface of the first vibratory plate 18a to the third arm 32c, whereas the second piezoelectric/electrostrictive element 20b is mounted on and extends from a side surface of the second vibratory plate 18b to the fourth arm 32d.

When the first piezoelectric/electrostrictive element 20a actuates the first vibratory plate 18a so as to curve outwardly in a direction to bring the first arm 32a away from the fourth arm 32d, and the second piezoelectric/electrostrictive element 20b actuates the second vibratory plate 18b so as to curve outwardly in a direction to bring the second arm 32b away from the third arm 32c, the rotor 12 is angularly displaced clockwise in FIG. 6.

Conversely, when the first piezoelectric/electrostrictive element 20a actuates the first vibratory plate 18a so as to curve inwardly in a direction to bring the first arm 32a toward the fourth arm 32d, and the second piezoelectric/electrostrictive element 20b actuates the second vibratory plate 18b so as to curve inwardly in a direction to bring the second arm 32b toward the third arm 32c, the rotor 12 is angularly displaced counterclockwise in FIG. 6.

In the third piezoelectric/electrostrictive device 10C, as with the first piezoelectric/electrostrictive device 10A, therefore, when the rotor 12 and an object to which the rotor 12 is connected are angularly displaced, movement of the center of gravity of the rotor 12 is small. Therefore, reactive forces generated in a region (i.e., a region of the central member 30 or the third arm 32c and the fourth arm 32d) at which the third piezoelectric/electrostrictive device 10C is fixed in place are small, and the third piezoelectric/electrostrictive device 10C can actuate the rotor 12 and the object under an easy control with an increased actuating frequency and an increased response speed.

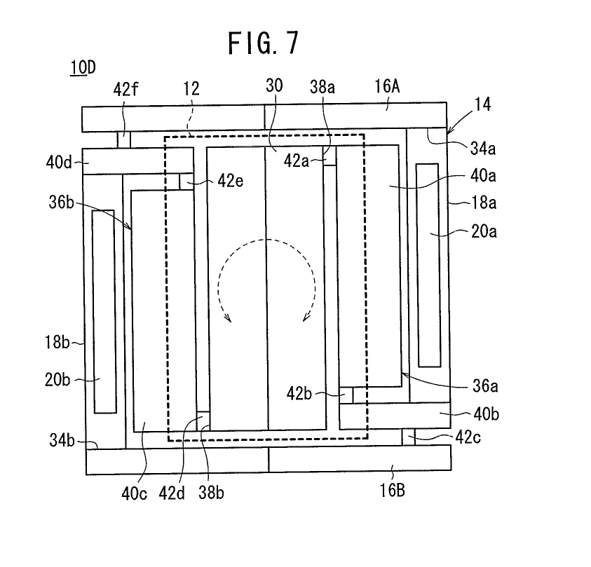

A piezoelectric/electrostrictive device 10D according to a fourth embodiment (hereinafter referred to as a fourth piezoelectric/electrostrictive device 10D) of the present invention shall be described below with reference to FIG. 7.

As shown in FIG. 7, the fourth piezoelectric/electrostrictive device 10D comprises a rotor 12 substantially in the form of a rectangular parallelepiped, and a rotary actuator 14 for angularly displacing the rotor 12.

The rotary actuator 14 includes a first stationary member 16A and a second stationary member 16B, which are spaced from each other, a central member 30 disposed between the first stationary member 16A and the second stationary member 16B and extending in a first direction, a first vibratory plate 18a extending from a first end 34a of the first stationary member 16A toward the second stationary member 16B, a second vibratory plate 18b extending from a second end 34b, which is diagonally opposite to the first end 34a, of the second stationary member 16B toward the first stationary member 16A, a first piezoelectric/electrostrictive element 20a mounted on a principal surface of the first vibratory plate 18a for actuating the first vibratory plate 18a, a second piezoelectric/electrostrictive element 20b mounted on a principal surface of the second vibratory plate 18b for actuating the second vibratory plate 18b, a first displacement transmitter 36a, and a second displacement transmitter 36b. The rotor 12 is secured to the central member 30 by an adhesive, for example.

The first displacement transmitter 36a is connected between a third end 38a, which is closer to the first stationary member 16A, of the central member 30, on a surface thereof which faces the first vibratory plate 18a, and an end of the first vibratory plate 18a. The first displacement transmitter 36a serves to transmit displacement of the first vibratory plate 18a to the central member 30.

The first displacement transmitter 36a has an elongate rectangular wide first flat plate 40a, and an elongate rectangular narrow second flat plate 40b.

The first flat plate 40a has a longer side disposed in facing relation to a side surface of the central member 30, and is connected to the central member 30 on the third end 38a thereof by a first hinge 42a.

The second flat plate 40b has a longer side thereof disposed in facing relation to a shorter side of the first flat plate 40a, and a shorter side thereof disposed in facing relation to the side surface of the central member 30. The second flat plate 40b is connected to the first flat plate 40a by a second hinge 42b that is disposed between a portion of a longer side thereof, which is close to the central member 30, and a portion of the shorter side of the first flat plate 40a, which is close to the central member 30. The second flat plate 40b has an opposite longer side connected to the second stationary member 16B by a third hinge 42c.

The second displacement transmitter 36b is connected between a fourth end 38b, which is closer to the second stationary member 16B, of the central member 30, on a surface thereof which faces the second vibratory plate 18b, and an end of the second vibratory plate 18b. The second displacement transmitter 36b serves to transmit displacement of the second vibratory plate 18b to the central member 30.

The second displacement transmitter 36b has an elongate rectangular wide third flat plate 40c and an elongate rectangular narrow fourth flat plate 40d.

The third flat plate 40c has a longer side disposed in facing relation to an opposite side surface of the central member 30, and is connected to the central member 30 by a fourth hinge 42d on the fourth end 38b.

The fourth flat plate 40d has a longer side thereof disposed in facing relation to a shorter side of the third flat plate 40c, and a shorter side thereof disposed in facing relation to the opposite side surface of the central member 30. The fourth flat plate 40d is connected to the third flat plate 40c by a fifth hinge 42e that is disposed between a portion of a longer side thereof, which is close to the central member 30, and a portion of the shorter side of the third flat plate 40c, which is close to the central member 30. The fourth flat plate 40d has an opposite longer side connected to the first stationary member 16A by a sixth hinge 42f.

When the first piezoelectric/electrostrictive element 20a actuates the first vibratory plate 18a so as to develop a compressive strain in the first vibratory plate 18a, and the second piezoelectric/electrostrictive element 20b actuates the second vibratory plate 18b so as to develop a compressive strain in the second vibratory plate 18b, the rotor 12 is angularly displaced counterclockwise in FIG. 7.

Conversely, when the first piezoelectric/electrostrictive element 20a actuates the first vibratory plate 18a so as to develop a tensile strain in the first vibratory plate 18a, and the second piezoelectric/electrostrictive element 20b actuates the second vibratory plate 18b so as to develop a tensile strain in the second vibratory plate 18b, the rotor 12 is angularly displaced clockwise in FIG. 7.

In the fourth piezoelectric/electrostrictive device 10D, as with the first piezoelectric/electrostrictive device 10A, therefore, when the rotor 12 and an object to which the rotor 12 is connected are angularly displaced, any movement of the center of gravity of the rotor 12 is small. Therefore, reactive forces generated in a region (i.e., a region of the first stationary member 16A and the second stationary member 16B) at which the fourth piezoelectric/electrostrictive device 10D is fixed in place are small, and the fourth piezoelectric/electrostrictive device 10D can actuate the rotor 12 and the object under an easy control with an increased actuating frequency and an increased response speed.

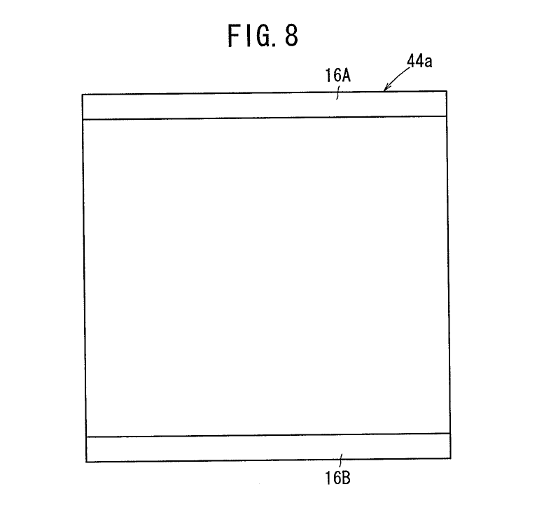

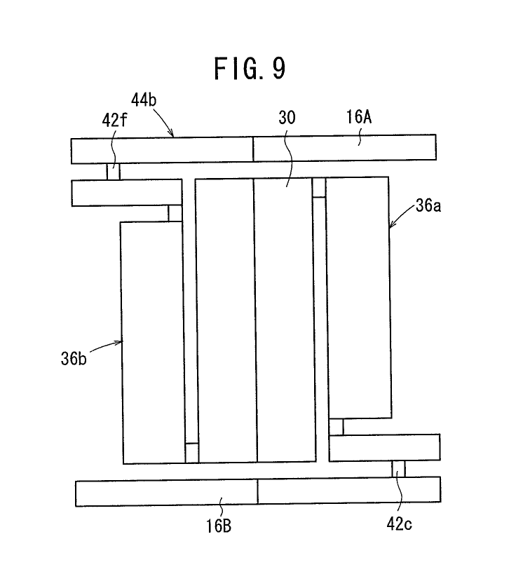

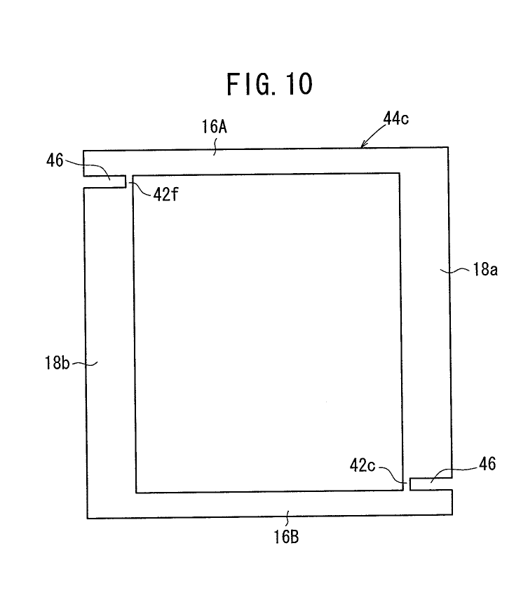

If the rotary actuator 14 of the fourth piezoelectric/electrostrictive device 10D is made of ceramics, then a first ceramic substrate 44a, which serves as a base as shown in FIG. 8, a second ceramic substrate 44b incorporating the first stationary member 16A, the second stationary member 16B, the central member 30, the first displacement transmitter 36a, and the second displacement transmitter 36b as shown in FIG. 9, and a frame-shaped third ceramic substrate 44c, having the first vibratory plate 18a and the second vibratory plate 18b as shown in FIG. 10, may be stacked together, wherein only portions of the first through third ceramic substrates 44a through 44c, which serve as the first stationary member 16A and the second stationary member 16B, are secured in place by an adhesive. The third ceramic substrate 44c may have recesses 46 defined therein, forming the third hinge 42c and the sixth hinge 42f.

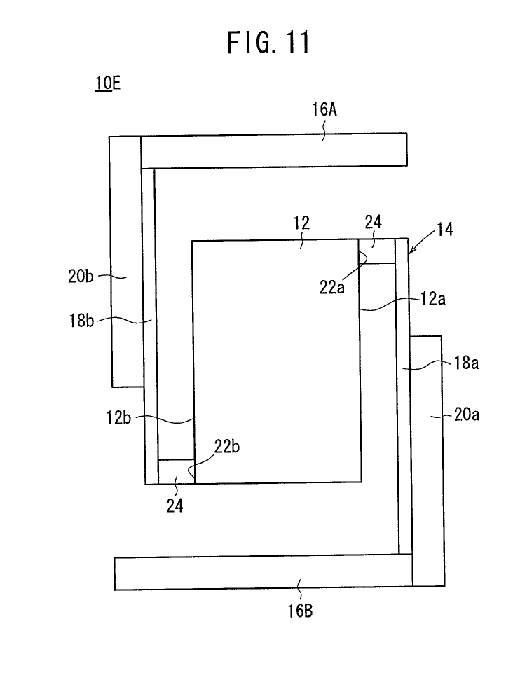

A piezoelectric/electrostrictive device 10E according to a fifth embodiment (hereinafter referred to a fifth piezoelectric/electrostrictive device 10E) of the present invention shall be described below with reference to FIG. 11.

As shown in FIG. 11, the fifth piezoelectric/electrostrictive device 10E comprises a rotor 12 substantially in the form of a rectangular parallelepiped, the rotor 12 having a pair of opposite surfaces 12a, 12b, and a rotary actuator 14 for angularly displacing the rotor 12.

The rotary actuator 14 includes a first stationary member 16A and a second stationary member 16B, which are made of metal and spaced from each other, a first metal vibratory plate 18a extending from the first stationary member 16A toward the second stationary member 16B, a second metal vibratory plate 18b extending from the second stationary member 16B toward the first stationary member 16A, a first piezoelectric/electrostrictive element 20a mounted on a side surface of the first vibratory plate 18a for actuating the first vibratory plate 18a, and a second piezoelectric/electrostrictive element 20b mounted on a side surface of the second vibratory plate 18b for actuating the second vibratory plate 18b.

Of the opposite surfaces 12a, 12b of the rotor 12, the surface 12a has a first end 22a secured to the first vibratory plate 18a by an adhesive 24, for example, whereas the other surface 12b has a second end 22b, which is diagonally opposite to the first end 22a, and which is secured to the second vibratory plate 18b by an adhesive 24, for example.

The fifth piezoelectric/electrostrictive device 10E is similar to the second piezoelectric/electrostrictive device 10B shown in FIG. 2, except that the first stationary member 16A, the second stationary member 16B, the first vibratory plate 18a, and the second vibratory plate 18b are all made of metal.

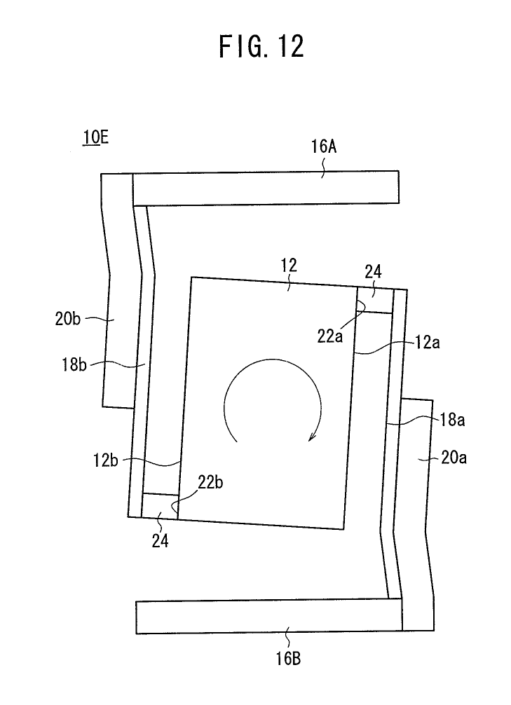

When the first piezoelectric/electrostrictive element 20a actuates the first vibratory plate 18a so as to curve outwardly and the second piezoelectric/electrostrictive element 20b actuates the second vibratory plate 18b so as to curve outwardly, the rotor 12 is angularly displaced clockwise in FIG. 12.

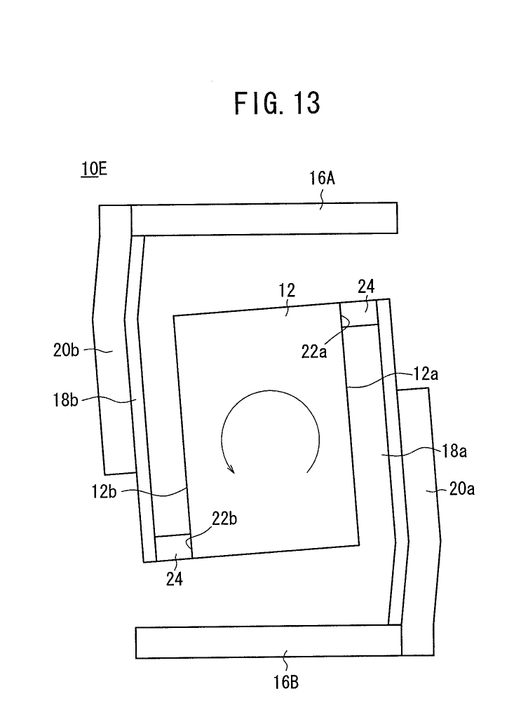

Conversely, when the first piezoelectric/electrostrictive element 20a actuates the first vibratory plate 18a so as to curve inwardly and the second piezoelectric/electrostrictive element 20b actuates the second vibratory plate 18b so as to curve inwardly, the rotor 12 is angularly displaced counterclockwise in FIG. 13.

With the fifth piezoelectric/electrostrictive device 10E, as with the first piezoelectric/electrostrictive device 10A, therefore, when the rotor 12 and an object to which the rotor 12 is connected are angularly displaced, any movement of the center of gravity of the rotor 12 is small. Therefore, reactive forces generated in a region (i.e., a region of the first stationary member 16A and the second stationary member 16B) at which the fifth piezoelectric/electrostrictive device 10E is fixed in place are small, and the fifth piezoelectric/electrostrictive device 10E can actuate the rotor 12 and the object under an easy control with an increased actuating frequency and an increased response speed.

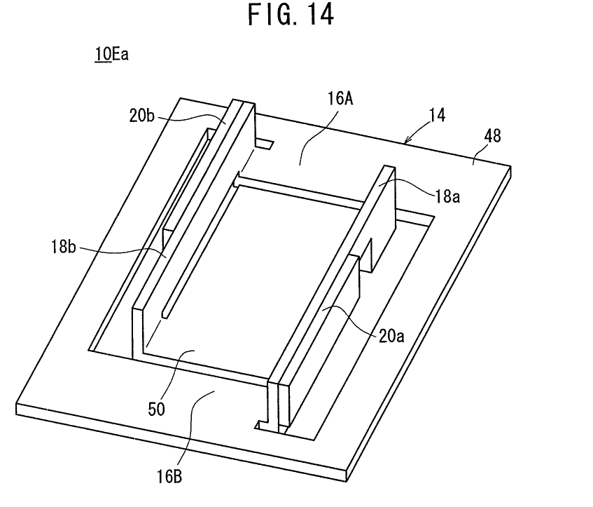

In the above embodiment, the first stationary member 16A and the second stationary member 16B are separate from each other. FIG. 14 shows a modified piezoelectric/electrostrictive device 10Ea, wherein the first stationary member 16A and the second stationary member 16B are integrally combined with each other by a metal frame 48. A rotor mount 50 is joined to an end of the first vibratory plate 18a and to an end of the second vibratory plate 18b, wherein the rotor 12 (not shown in FIG. 14) is mounted on the rotor mount 50.

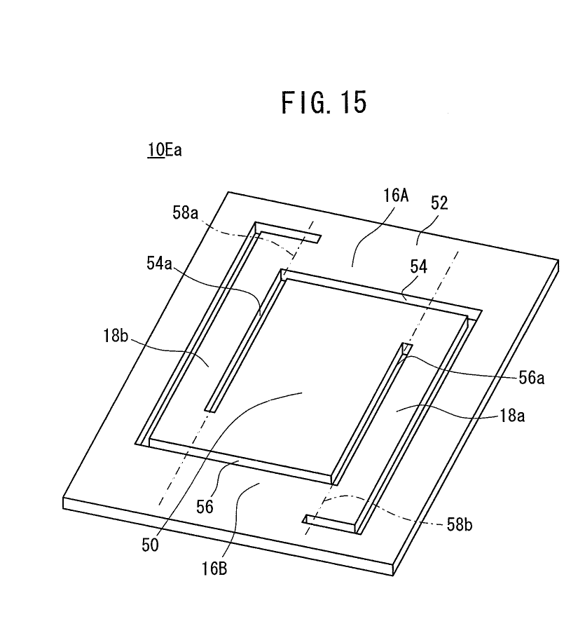

The modified piezoelectric/electrostrictive device 10Ea is fabricated as follows: As shown in FIG. 15, a single metal plate 52 is prepared. Then, the metal plate 52 is punched to form a first slot 54 and a second slot 56 therein, thereby shaping the first stationary member 16A, the second stationary member 16B, the first vibratory plate 18a, the second vibratory plate 18b, and the rotor mount 50.

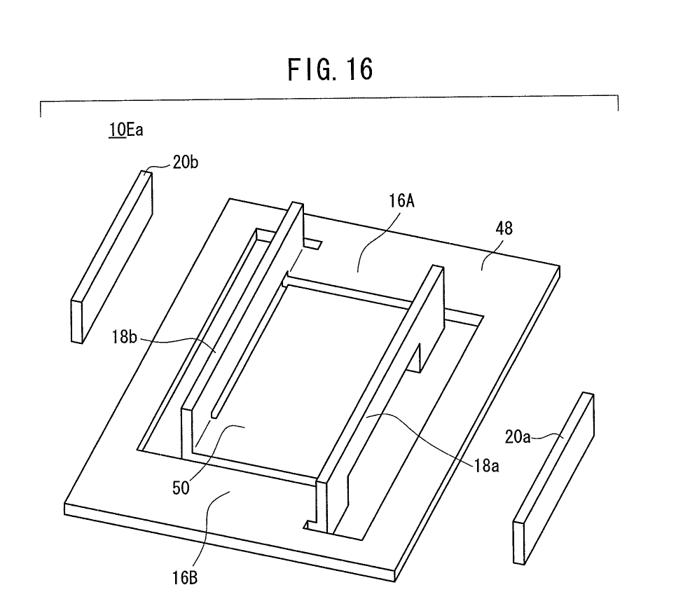

Thereafter, the second vibratory plate 18b and the first vibratory plate 18a are bent upwardly respectively about a straight portion 54a of the first slot 54, which extends along the second vibratory plate 18b as a first fold line 58a, and a straight portion 56a of the second slot 56, which extends along the first vibratory plate 18a as a second fold line 58b, as shown in FIG. 16. At this time, the metal frame 48 is formed.

Thereafter, the first piezoelectric/electrostrictive element 20a is secured onto a side surface of the first vibratory plate 18a by an adhesive, for example, whereas the second piezoelectric/electrostrictive element 20b is secured onto a side surface of the second vibratory plate 18b by an adhesive, for example.

Then, as shown in FIG. 14, the rotor 12, not shown, is mounted on the rotor mount 50, thereby completing the modified piezoelectric/electrostrictive device 10Ea.

Since the piezoelectric/electrostrictive device 10Ea can easily be produced by punching and bending a single metal plate 52, the manufacturing process is simplified and manufacturing costs are lowered.

Inasmuch as all components of the rotary actuator 14 are made of metal, the modified piezoelectric/electrostrictive device 10Ea offers the following additional advantages:

Since the rotary actuator 14 is made of metal, it is highly resistant to shocks. Because the rotor 12 is angularly displaced when the first vibratory plate 18a and the second vibratory plate 18b that face each other are bent, stresses are distributed within the rotary actuator 14. Accordingly, the piezoelectric/electrostrictive device 10Ea is less liable to suffer from metal fatigue, and has a longer service life and better reliability.

If the rotary actuator is made of ceramics, then stresses tend to concentrate on the hinges thereof. However, such stress concentration can be avoided if the rotary actuator is made of metal.

Since the first piezoelectric/electrostrictive element 20a and the second piezoelectric/electrostrictive element 20b are formed as a unimorph/bimorph structure on a metal base, they are less subject to stress concentration due to electrostrictive strains, external forces, or shocks, and further, are highly resistant to shocks and thus have a longer service life.

The rotary actuator 14 made of metal is simple in structure. Since the first vibratory plate 18a and the second vibratory plate 18b are surrounded by the frame 48, the rotary actuator 14 can be designed so as to occupy a reduced volume and have a reduced weight, with greater freedom than if the rotary actuator were constructed of a laminated assembly of green sheets.

Since the first vibratory plate 18a and the second vibratory plate 18b extend perpendicularly from the metal plate 52, the rotary actuator 14 is highly resistant to vertical shocks, in particular, and can produce a large angular displacement under relatively weak forces.

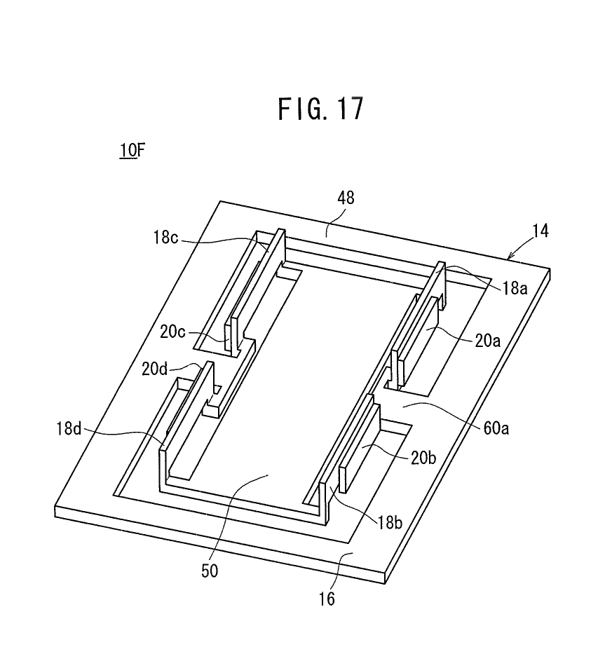

A piezoelectric/electrostrictive device 10F according to a sixth embodiment (hereinafter referred to as a sixth piezoelectric/electrostrictive device 10F) of the present invention shall be described below with reference to FIG. 17.

As shown in FIG. 17, the sixth piezoelectric/electrostrictive device 10F comprises a rotor 12 (not shown in FIG. 17) substantially in the form of a rectangular parallelepiped, and a rotary actuator 14 for angularly displacing the rotor 12.

The rotary actuator 14 includes a frame-shaped stationary member 16 made of metal, a first metal vibratory plate 18a having an end secured to the stationary member 16 and extending in one direction, a second metal vibratory plate 18b having an end secured to the stationary member 16 and extending along an extension of the first vibratory plate 18a, a third metal vibratory plate 18c having an end secured to the stationary member 16, the third vibratory plate 18c being spaced from the first vibratory plate 18a and extending substantially parallel thereto, a fourth metal vibratory plate 18d having an end secured to the stationary member 16 and extending along an extension of the third vibratory plate 18c, a rotor mount 50 joined to ends of the first through fourth vibratory plates 18a through 18d, a first piezoelectric/electrostrictive element 20a mounted on a side surface of the first vibratory plate 18a for actuating the first vibratory plate 18a, a second piezoelectric/electrostrictive element 20b mounted on a side surface of the second vibratory plate 18b for actuating the second vibratory plate 18b, a third piezoelectric/electrostrictive element 20c mounted on a side surface of the third vibratory plate 18c for actuating the third vibratory plate 18c, and a fourth piezoelectric/electrostrictive element 20d mounted on a side surface of the fourth vibratory plate 18d for actuating the fourth vibratory plate 18d. The rotor 12 is fixedly mounted on a rotor mount 50, although the rotor 12 has been omitted from illustration in FIG. 17.

The stationary member 16 comprises a metal frame 48. The first vibratory plate 18a and the second vibratory plate 18b are secured to an eleventh arm 60a extending from one of two opposite surfaces of the frame 48 to the other surface thereof. The third vibratory plate 1.8c and the fourth vibratory plate 18d are secured to a twelfth arm 60b extending from the other surface of the frame 48 to the one surface thereof.

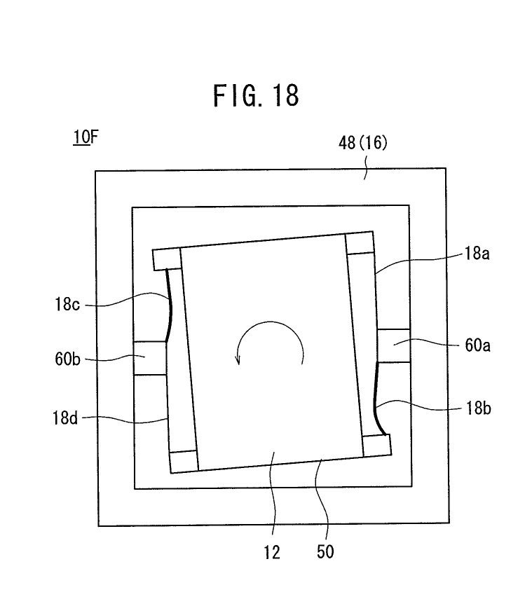

When the second piezoelectric/electrostrictive element 20b actuates the second vibratory plate 18b so as to develop a compressive strain in the second vibratory plate 18b, and the third piezoelectric/electrostrictive element 20c actuates the third vibratory plate 18c so as to develop a compressive strain in the third vibratory plate 18c, the rotor 12 is angularly displaced counterclockwise in FIG. 18.

Conversely, when the first piezoelectric/electrostrictive element 20a actuates the first vibratory plate 18a so as to develop a compressive strain in the first vibratory plate 18a, and the fourth piezoelectric/electrostrictive element 20d actuates the fourth vibratory plate 18d so as to develop a compressive strain in the fourth vibratory plate 18d, the rotor 12 is angularly displaced clockwise in FIG. 18.

In the sixth piezoelectric/electrostrictive device 10F, as with the first piezoelectric/electrostrictive device 10A, therefore, when the rotor 12 and an object to which the rotor 12 is connected are angularly displaced, any movement of the center of gravity of the rotor 12 is small. Therefore, reactive forces generated in a region (i.e., a region of the stationary member 16) at which the sixth piezoelectric/electrostrictive device 10F is fixed in place are small, and the sixth piezoelectric/electrostrictive device 10F can actuate the rotor 12 and the object under an easy control with an increased actuating frequency and an increased response speed. Furthermore, since the sixth piezoelectric/electrostrictive device 10F is made of metal, as with the fifth piezoelectric/electrostrictive device 10E, it offers advantages based on the components made of metal.

The first through fourth piezoelectric/electrostrictive elements 20a through 20d may be controlled so as to enable the rotor 12 to be torsionally and angularly displaced at the same time.

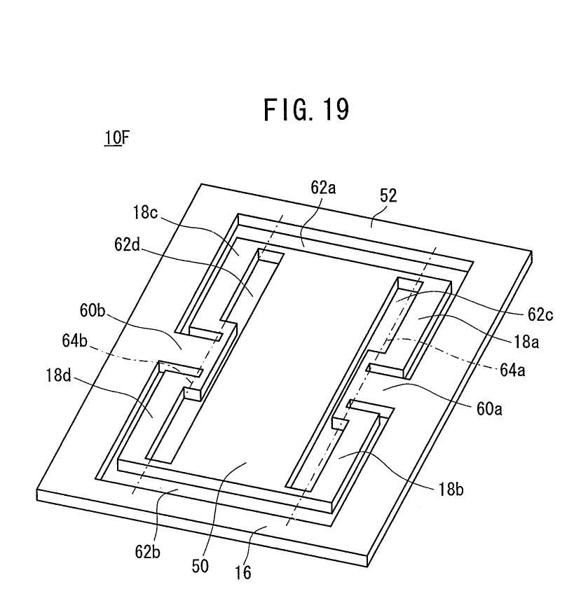

The sixth piezoelectric/electrostrictive device 10F is fabricated as follows: As shown in FIG. 19, a single metal plate 52 is prepared. Then, the metal plate 52 is punched to form eleventh through fourteenth slots 62a through 62d therein, thereby shaping the stationary member 16, the eleventh arm 60a, the twelfth arm 60b, the first through fourth vibratory plates 18a through 18d, and the rotor mount 50.

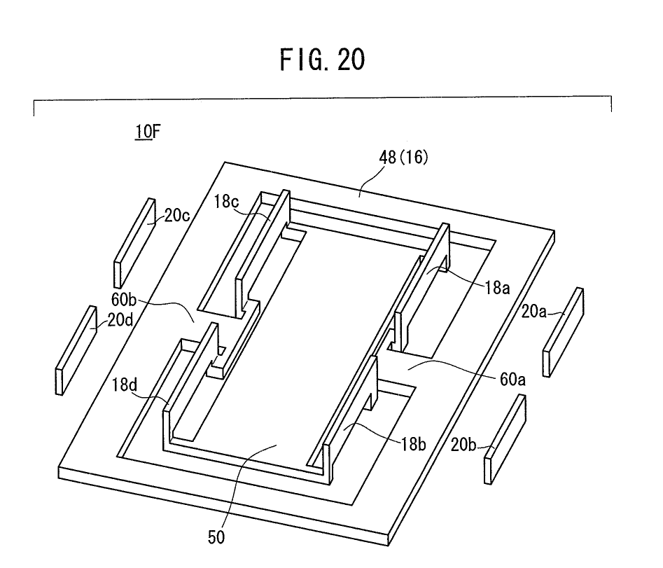

Thereafter, the first through fourth vibratory plates 18a through 18d are bent upwardly, as shown in FIG. 20, about a straight portion, which interconnects ends of the eleventh slot 62a and the twelfth slot 62b, and a straight portion, which interconnects opposite ends of the eleventh slot 62a and the twelfth slot 62b, forming an eleventh fold line 64a and a twelfth fold line 64b.

Thereafter, the first through fourth piezoelectric/electrostrictive elements 20a through 20d are secured to respective side surfaces of the first through fourth vibratory plates 18a through 18d by an adhesive, for example.

Then, as shown in FIG. 17, the rotor 12, not shown, is mounted on the rotor mount 50, thereby completing the sixth piezoelectric/electrostrictive device 10F.

Since the sixth piezoelectric/electrostrictive device 10F can easily be produced by punching and bending a single metal plate 52, the manufacturing process is simplified and manufacturing costs are lowered.

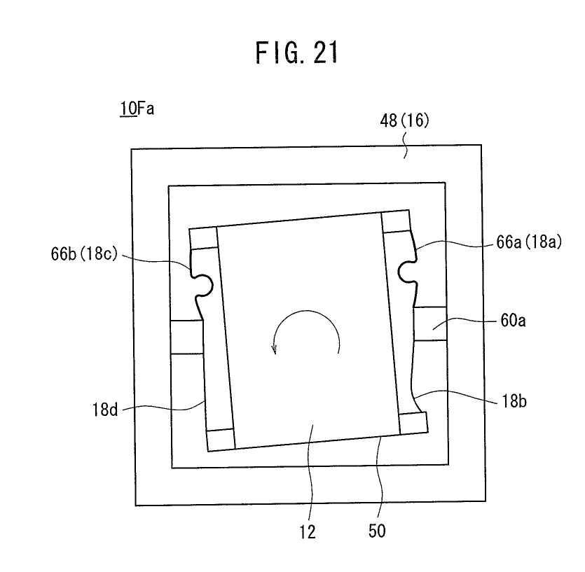

In the above embodiment, the first through fourth piezoelectric/electrostrictive elements 20a through 20d are secured to respective side surfaces of the first through fourth vibratory plates 18a through 18d by an adhesive. FIG. 21 shows a piezoelectric/electrostrictive device 10Fa according to a first modification. In the piezoelectric/electrostrictive device 10Fa according to the first modification, the first vibratory plate 18a comprises a first compression spring 66a, and the third vibratory plate 18c comprises a second compression spring 66b.

When the first piezoelectric/electrostrictive element 20a actuates the first vibratory plate 18a so as to develop a compressive strain therein, the first compression spring 66a is extended. Therefore, the rotor 12 is angularly displaced counterclockwise in FIG. 21.

Conversely, when the fourth piezoelectric/electrostrictive element 20d actuates the fourth vibratory plate 18d so as to develop a compressive strain therein, the second compression spring 66b is extended. Therefore, the rotor 12 is angularly displaced clockwise in FIG. 21.

The first compression spring 66a and the second compression spring 66b make it possible to greatly increase the angular displacement of the rotor 12.

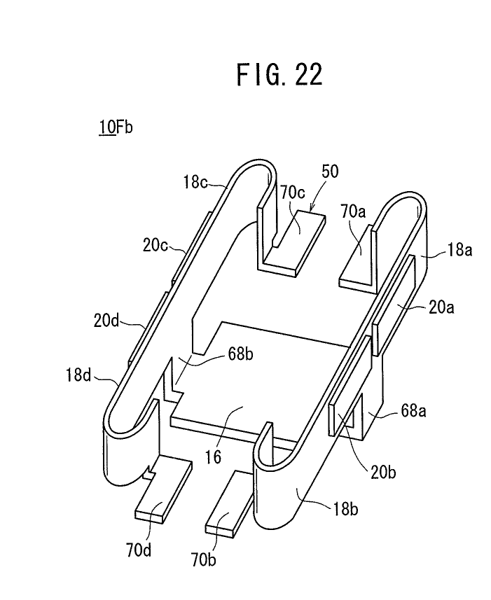

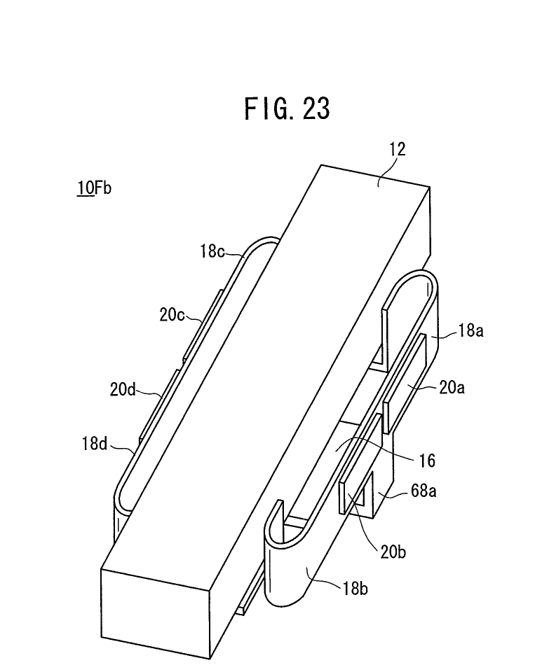

In the above embodiment, the stationary member 16 is in the form of a frame 48. FIG. 22 shows a piezoelectric/electrostrictive device 10Fb according to a second modification. In the modified piezoelectric/electrostrictive device 10Fb, the stationary member 16 has a rectangular planar shape. The first vibratory plate 18a and the second vibratory plate 18b are secured to a twenty-first arm 68a extending upwardly from one of two opposite surfaces of the stationary member 16, whereas the third vibratory plate 18c and the fourth vibratory plate 18d are secured to a twenty-second arm 68b extending upwardly from the other of the two opposite surfaces of the stationary member 16. The rotor mount 50 comprises first through fourth feet 70a through 70d, which are fixed to respective ends of the first through fourth vibratory plates 18a through 18d. The rotor 12 is mounted on the first through fourth feet 70a through 70d, as shown in FIG. 23.

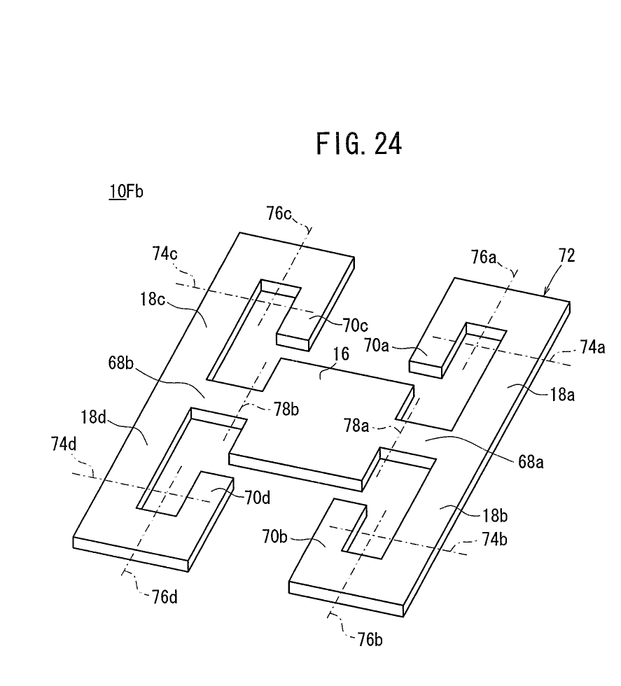

The piezoelectric/electrostrictive device 10Fb according to the second modification is fabricated as follows: As shown in FIG. 24, a single metal plate is punched to produce a blank plate 72 made up of the stationary member 16, the twenty-first arm 68a, the twenty-second arm 68b, the first through fourth vibratory plates 18a through 18d, and the first through fourth feet 70a through 70d.

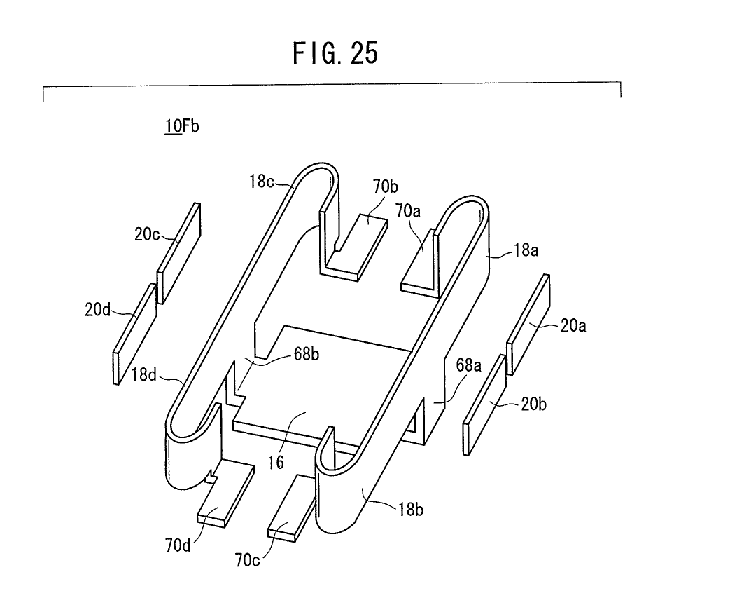

Thereafter, the end of the first vibratory plate 18a, the end of the second vibratory plate 18b, the end of the third vibratory plate 18c, and the end of the fourth vibratory plate 18d are bent respectively about a twenty-first fold line 74a near the end of the first vibratory plate 18a, a twenty-second fold line 74b near the end of the second vibratory plate 18b, a twenty-third fold line 74c near the end of the third vibratory plate 18c, and a twenty-fourth fold line 74d near the end of the fourth vibratory plate 18d. Then, the end of the first vibratory plate 18a, the end of the second vibratory plate 18b, the end of the third vibratory plate 18c, and the end of the fourth vibratory plate 18d are bent respectively about a first boundary line 76a between the first vibratory plate 18a and the first foot 70a, a second boundary line 76b between the second vibratory plate 18b and the second foot 70b, a third boundary line 76c between the third vibratory plate 18c and the third foot 70c, and a fourth boundary line 76d between the fourth vibratory plate 18d and the fourth foot 70d. In addition, the twenty-first arm 68a is bent about a twenty-fifth fold line 78a near the stationary member 16, and the twenty-second arm 68b is bent about a twenty-sixth fold line 78b near the stationary member 16. The first through fourth vibratory plates 18a through 18d are thus bent upwardly, whereas the first through fourth feet 70a through 70d lie horizontally, as shown in FIG. 25.

Thereafter, the first through fourth piezoelectric/electrostrictive elements 20a through 20d are secured to respective side surfaces of the first through fourth vibratory plates 18a through 18d by an adhesive, for example.

The rotor 12 is then mounted on the horizontal first through fourth feet 70a through 70d, thereby completing the piezoelectric/electrostrictive device 10Fb according to the second modification, as shown in FIG. 23.

Since the piezoelectric/electrostrictive device 10Fb can easily be produced by punching and bending a single metal plate, the manufacturing process is simplified and manufacturing costs are lowered.

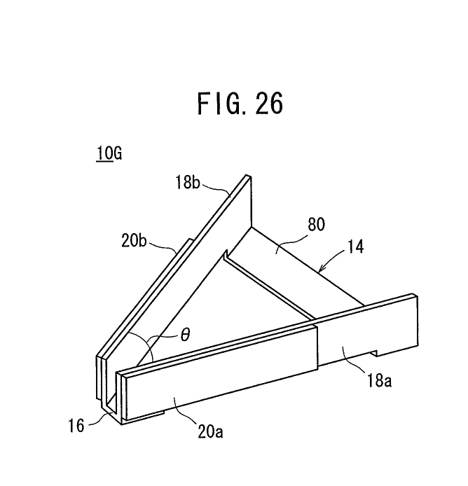

A piezoelectric/electrostrictive device 10G according to a seventh embodiment (hereinafter referred to as a seventh piezoelectric/electrostrictive device 10G) of the present invention shall be described below with reference to FIG. 26.

As shown in FIG. 26, the seventh piezoelectric/electrostrictive device 10G comprises a rotor 12 (not shown in FIG. 26) substantially in the form of a rectangular parallelepiped, and a rotary actuator 14 for angularly displacing the rotor 12.

The rotary actuator 14 includes a stationary member 16 made of metal, a first vibratory plate 18a and a second vibratory plate 18b, which have respective ends secured to the stationary member 16, and which also are made of metal and angularly spaced from each other by a predetermined angle 0, a metal movable member 80 connected between the other end of the first vibratory plate 18a and the other end of the second vibratory plate 18b, a first piezoelectric/electrostrictive element 20a mounted on a side surface of the first vibratory plate 18a for actuating the first vibratory plate 18a, and a second piezoelectric/electrostrictive element 20b mounted on a side surface of the second vibratory plate 18b for actuating the second vibratory plate 18b. The rotor 12, not shown, is secured, for example, to a lower surface of the movable member 80 by an adhesive or the like.

The stationary member 16, the first vibratory plate 18a, the second vibratory plate 18b, and the movable member 80 may easily be fabricated by punching and bending a single metal plate, for example.

When the first piezoelectric/electrostrictive element 20a actuates the first vibratory plate 18a to develop a compressive strain in the first vibratory plate 18a, and the second piezoelectric/electrostrictive element 20b actuates the second vibratory plate 18b to develop a tensile strain in the second vibratory plate 18b, the rotor 12 is angularly displaced clockwise in FIG. 26.

Conversely, when the first piezoelectric/electrostrictive element 20a actuates the first vibratory plate 18a to develop a tensile strain in the first vibratory plate 18a, and the second piezoelectric/electrostrictive element 20b actuates the second vibratory plate 18b to develop a compressive strain in the second vibratory plate 18b, the rotor 12 is angularly displaced counterclockwise in FIG. 26.

Since the rotary actuator 14 angularly moves about a center near the point of intersection between an extension of the first vibratory plate 18a and an extension of the second vibratory plate 18b, the rotor 12 should preferably be secured to the movable member 80 such that the center of gravity of the rotor 12 is in conformity with the center of angular movement.

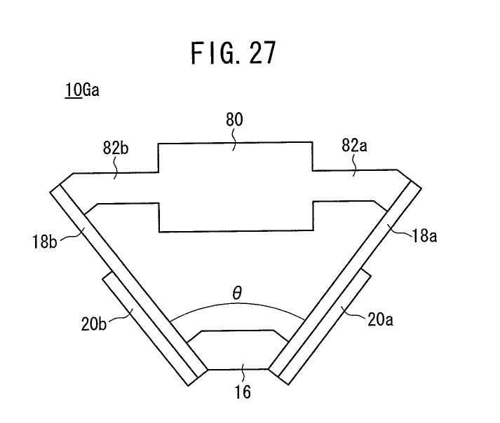

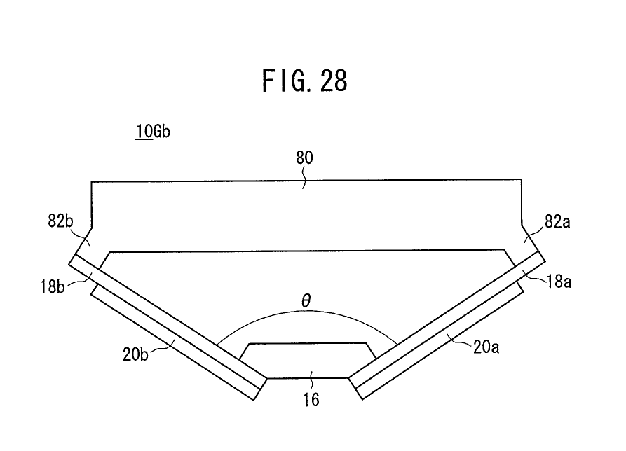

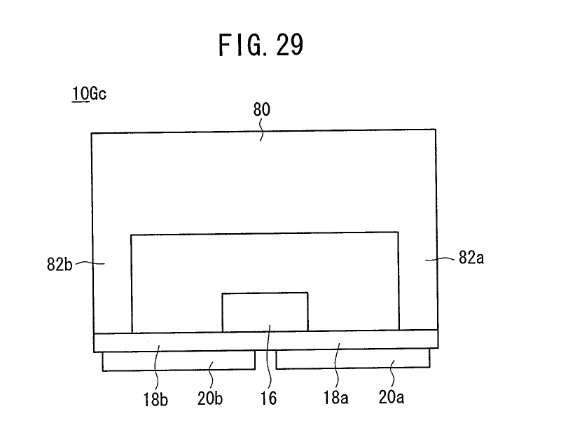

The predetermined angle θ may be an acute angle, as indicated in the piezoelectric/electrostrictive device 10Ga according to a first modification shown in FIG. 27, or may be an obtuse angle, as indicated in the piezoelectric/electrostrictive device 10Gb according to a second modification shown in FIG. 28. The predetermined angle θ may be 90 degrees, or may be 180 degrees, as indicated in the piezoelectric/electrostrictive device 10Gc according to a third modification shown in FIG. 29. In the piezoelectric/electrostrictive devices 10Ga, 10Gb and 10Gc according to the first through third modifications, one side surface of the movable member 80 and an end of the first vibratory plate 18a are integrally connected to each other by a thirty-first arm 82a, whereas the other side surface of the movable member 80 and an end of the second vibratory plate 18b are integrally connected to each other by a thirty-second arm 82b.

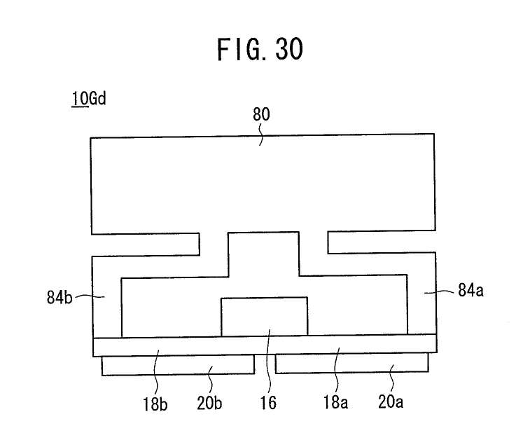

FIG. 30 shows a piezoelectric/electrostrictive device 10Gd according to a fourth modification. In the piezoelectric/electrostrictive device 10Gd, the predetermined angle θ is 180 degrees. A central portion of the surface of the movable member 80, which faces the stationary member 16, and an end of the first vibratory plate 18a are integrally connected to each other by an L-shaped forty-first arm 84a. The central portion of the surface of the movable member 80 and an end of the second vibratory plate 18b are integrally connected to each other by an L-shaped forty-second arm 84b.

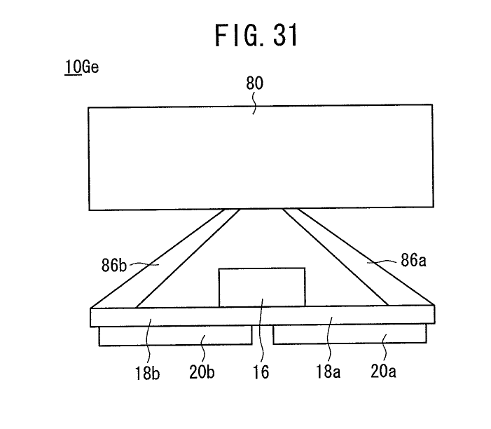

FIG. 31 shows a piezoelectric/electrostrictive device 10Ge according to a fifth modification. In the piezoelectric/electrostrictive device 10Ge, the predetermined angle θ is 180 degrees. A central portion of the surface of the movable member 80, which faces the first vibratory plate 18a and the second vibratory plate 18b, and an end of the first vibratory plate 18a are integrally connected to each other by a fifty-first arm 86a, which is progressively narrower toward the surface of the movable member 80. The central portion of the surface of the movable member 80 and an end of the second vibratory plate 18b are integrally connected to each other by a fifty-second arm 86b, which is progressively narrower toward the surface of the movable member 80.

With the piezoelectric/electrostrictive devices 10Gd, 10Ge according to the fourth and fifth modifications, since the joint between the first and second vibratory plates 18a, 18b and the movable member 80 is close to the center of rotation, the angular displacement of the movable member 80 is efficiently increased.

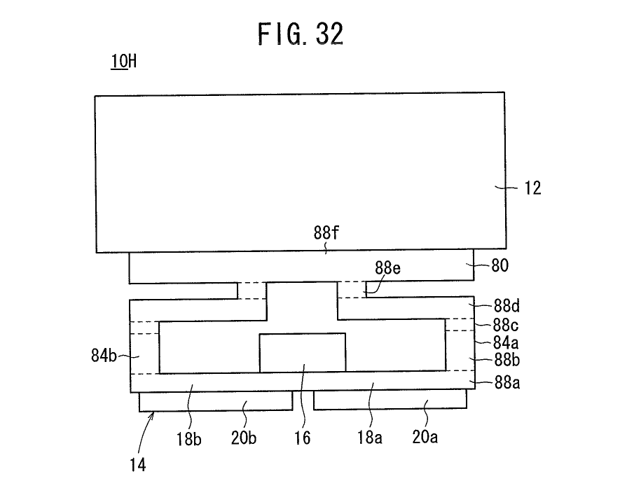

A piezoelectric/electrostrictive device 10H according to an eighth embodiment (hereinafter referred to as an eighth piezoelectric/electrostrictive device 10H) of the present invention shall be described below with reference to FIG. 32.

As shown in FIG. 32, the eighth piezoelectric/electrostrictive device 10H comprises a rotor 12 substantially in the form of a rectangular parallelepiped, and a rotary actuator 14 for angularly displacing the rotor 12.

The rotary actuator 14 is of a structure that is essentially the same as the rotary actuator 14 of the piezoelectric/electrostrictive device 10Gd according to the fourth modification of the seventh embodiment, but differs therefrom in that it comprises an integrally sintered assembly of laminated ceramic green sheets.

On an eleventh green sheet 88a, which serves as the first vibratory plate 18a and the second vibratory plate 18b, there are laminated and integrally sintered a twelfth green sheet 88b, which serves as the stationary member 16 and portions of the forty-first arm 84a and the forty-second arm 84b, thirteenth through fifteenth green sheets 88c through 88e, which serve as portions of the forty-first arm 84a and the forty-second arm 84b, and a sixteenth green sheet 88f, which serves as the movable member 80 with the rotor 12 mounted thereon. Each of the eleventh through sixteenth green sheets 88a through 88f comprises a single green sheet or a plurality of green sheets.

The first piezoelectric/electrostrictive element 20a is formed on the first vibratory plate 18a by screen printing, for example. Similarly, the second piezoelectric/ electrostrictive element 20b is formed on the second vibratory plate 18b by screen printing, for example.

When the first piezoelectric/electrostrictive element 20a and the second piezoelectric/electrostrictive element 20b actuate the first vibratory plate 18a and the second vibratory plate 18b, respectively, compressive and tensile strains are developed therein, which are combined with each other to control translation and angular displacement of the rotor 12.

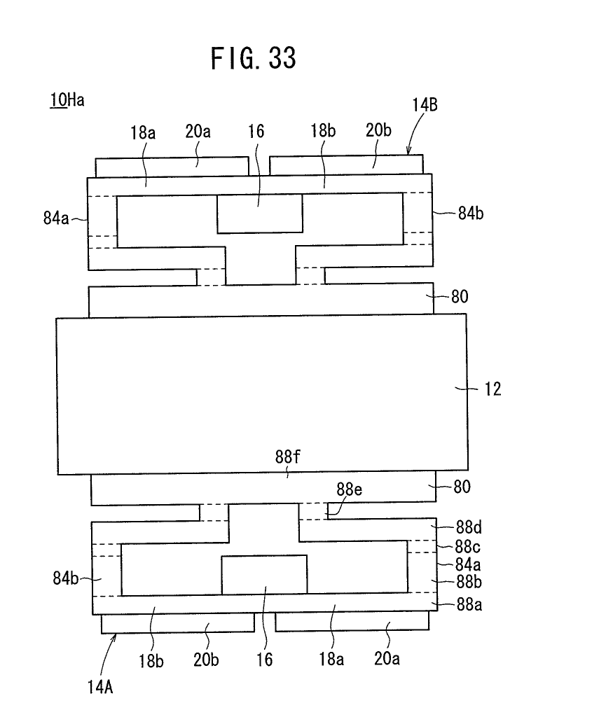

In the above embodiment, the rotary actuator 14 is disposed in facing relation to one surface of the rotor 12. FIG. 33 shows a piezoelectric/electrostrictive device 10Ha according to a first modification. In the piezoelectric/electrostrictive device 10Ha according to the first modification, a first rotary actuator 14A is disposed in facing relation to one surface of the rotor 12, and a second rotary actuator 14B is disposed in facing relation to an opposite surface of the rotor 12. Each of the first rotary actuator 14A and the second rotary actuator 14B has a structure which is identical to that of the rotary actuator 14 of the eighth piezoelectric/electrostrictive device 10H shown in FIG. 32.

When the four piezoelectric/electrostrictive elements, i.e., the two first piezoelectric/electrostrictive elements 20a and the two second piezoelectric/electrostrictive elements 20b, actuate the corresponding first and second vibratory plates 18a, 18b, translation and angular displacement of the rotor 12 are controlled.

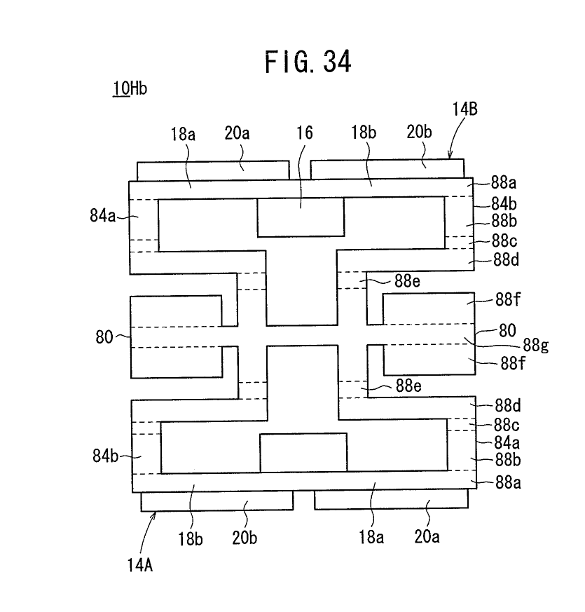

FIG. 34 shows a piezoelectric/electrostrictive device 10Hb according to a second modification. In the piezoelectric/electrostrictive device 10Hb according to the second modification, the first rotary actuator 14A and the second rotary actuator 14B are integrally combined with each other. On a fifteenth green sheet 88e of the first rotary actuator 14A, there are laminated a sixteenth green sheet 88f, which serves as a portion of the movable member 80 of the first rotary actuator 14A and portions of the forty-first arm 84a and the forty-second arm 84b, and a seventeenth green sheet 88g, which serves as a portion of the movable member 80. Furthermore, the sixteenth green sheet 88f, the fifteenth green sheet 88e, the fourteenth green sheet 88d, the thirteenth green sheet 88c, the twelfth green sheet 88b, and the eleventh green sheet 88a, which make up the second rotary actuator 14B, are laminated and integrally sintered.

The rotor 12 is secured to a principal surface of the movable member 80, which is provided by the sixteenth green sheet 88f and the seventeenth green sheet 88g, by an adhesive, for example.

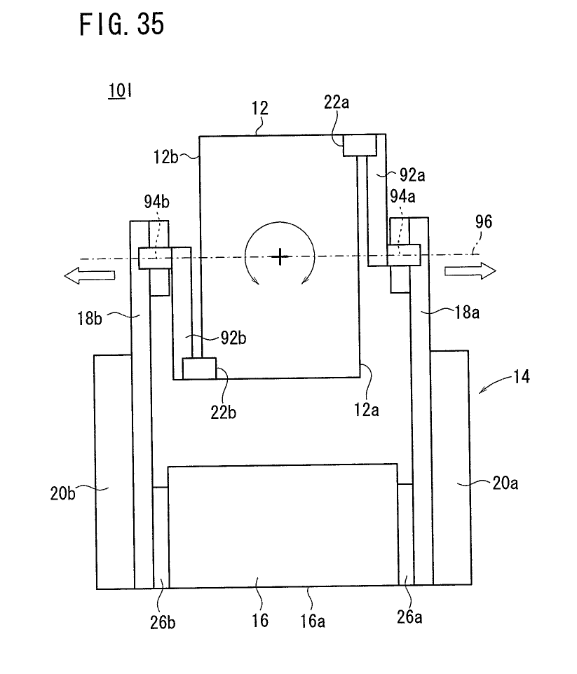

As shown in FIG. 35, a piezoelectric/electrostrictive device 10I according to a ninth embodiment (hereinafter referred to as a ninth piezoelectric/electrostrictive device 10I) of the present invention comprises a rotor 12 substantially in the form of a rectangular parallelepiped, together with a rotary actuator 14 for angularly displacing the rotor 12. As with the piezoelectric/electrostrictive device 10A, a slider, a sensor, a stage, or the like may be mounted on the rotor 12, or alternatively, the rotor 12 itself may comprise a slider, a stage, or the like.

The rotary actuator 14 has a stationary member 16, a first vibratory plate 18a and a second vibratory plate 18b, which extend in one direction from both sides of the stationary member 16, a first piezoelectric/electrostrictive element 20a mounted on and extending from a side surface of the first vibratory plate 18a to the stationary member 16 for actuating the first vibratory plate 18a, and a second piezoelectric/electrostrictive element 20b mounted on and extending from a side surface of the second vibratory plate 18b to the stationary member 16 for actuating the second vibratory plate 18b.

The first vibratory plate 18a extends in one direction from a position that is aligned with a lower end 16a of the stationary member 16, and has a first thick portion 90a on a distal end thereof, which faces the second vibratory plate 18b. Similarly, the second vibratory plate 18b extends in one direction from a position that is aligned with the lower end 16a of the stationary member 16, and has a second thick portion 90b on a distal end thereof, which faces the first vibratory plate 18a.

Of the opposite surfaces 12a, 12b of the rotor 12, the surface 12a has a first end 22a connected to the first thick portion 90a of the first vibratory plate 18a by a substantially Z-shaped first connector 92a, using an unillustrated adhesive. Similarly, the other surface 12b has a second end 22b connected to the second thick portion 90b of the second vibratory plate 18b by a substantially Z-shaped second connector 92b, using an unillustrated adhesive. The adhesive may comprise an ultraviolet-curable resin, an epoxy resin, or the like.

In the ninth piezoelectric/electrostrictive device 10, a first joint position 94a between the first connector 92a and the first vibratory plate 18a, and a second joint position 94b between the second connector 92b and the second vibratory plate 18b, are arranged in a substantially confronting positional relationship. The first joint position 94a and the second joint position 94b are disposed on a single extension 96, which includes the center of gravity of the rotor 12 located at the position indicated by “+” in FIG. 35.

The first end 22a at a joint position between the rotor 12 and the first connector 92a, and the second end 22b at a joint position between the rotor 12 and the second connector 92b, are positionally related to each other in point symmetry with respect to the center of gravity of the rotor 12.

A first plate member 26a used for positioning is interposed between the stationary member 16 and the first vibratory plate 18a, and a second plate member 26b used for positioning is interposed between the stationary member 16 and the second vibratory plate 18b.

When the first piezoelectric/electrostrictive element 20a actuates the first vibratory plate 18a so as to curve outwardly in a direction to bring the first thick portion 90a of the first vibratory plate 18a away from the second thick portion 90b of the second vibratory plate 18b, and the second piezoelectric/electrostrictive element 20b actuates the second vibratory plate 18b so as to curve outwardly in a direction to bring the second thick portion 90b of the second vibratory plate 18b away from the first thick portion 90a of the first vibratory plate 18a, the rotor 12 is angularly displaced clockwise in FIG. 35.

Conversely, when the first piezoelectric/electrostrictive element 20a actuates the first vibratory plate 18a so as to curve inwardly in a direction to bring the first thick portion 90a of the first vibratory plate 18a toward the second thick portion 90b of the second vibratory plate 18b, and the second piezoelectric/electrostrictive element 20b actuates the second vibratory plate 18b so as to curve inwardly in a direction to bring the second thick portion 90b of the second vibratory plate 18b toward the first thick portion 90a of the first vibratory plate 18a, the rotor 12 is angularly displaced counterclockwise in FIG. 35.

When the first piezoelectric/electrostrictive element 20a actuates the first vibratory plate 18a so as to curve outwardly, and the second piezoelectric/electrostrictive element 20b actuates the second vibratory plate 18b so as to curve inwardly, the rotor 12 is translated to the right in FIG. 35. When the first piezoelectric/electrostrictive element 20a actuates the first vibratory plate 18a so as to curve inwardly, and the second piezoelectric/electrostrictive element 20b actuates the second vibratory plate 18b so as to curve outwardly, the rotor 12 is translated to the left in FIG. 35.

The stationary member 16, the first vibratory plate 18a, the first thick portion 90a, the second vibratory plate 1.8b, the second thick portion 90b, the first plate member 26a, and the second plate member 26b may comprise an integrally sintered assembly of laminated ceramic green sheets. The first piezoelectric/electrostrictive element 20a and the second piezoelectric/electrostrictive element 20b may be formed by screen printing on respective side surfaces of the first vibratory plate 18a and the second vibratory plate 18b. Alternatively, the first vibratory plate 18a and the second vibratory plate 18b may be made of metal. If the first vibratory plate 18a and the second vibratory plate 18b are made of metal, then the first piezoelectric/electrostrictive element 20a and the second piezoelectric/electrostrictive element 20b are secured to respective side surfaces of the first vibratory plate 18a and the second vibratory plate 18b by an adhesive, for example.

With the ninth piezoelectric/electrostrictive device 10I, therefore, the first vibratory plate 18a and the second vibratory plate 18b sandwich the rotor 12 with the first connector 92a and the second connector 92b interposed therebetween, and are actuated respectively by the first piezoelectric/electrostrictive element 20a and the second piezoelectric/electrostrictive element 20b in order to angularly displace the rotor 21.

In particular, since the first joint position 94a between the first connector 92a and the first vibratory plate 18a, and the second joint position 94b between the second connector 92b and the second vibratory plate 18b, are in a substantially confronting positional relationship, and since the first end 22a of the rotor 12 and the second end 22b of the rotor 12 are positionally related to each other in point symmetry with respect to the center of gravity (center of rotation) of the rotor 12, the center of gravity of the rotor 12 makes almost no movement when the rotor 12 is angularly displaced.

When the rotor 12 or an object to which the rotor 12 is fixed is angularly displaced, because any movement of the center of gravity of the rotor 12 is small, reactive forces generated in a region (i.e., a region of the stationary member 16) at which the ninth piezoelectric/electrostrictive device 10I is fixed in place are small, and the ninth piezoelectric/electrostrictive device 10I can actuate the object under an easy control with an increased actuating frequency and an increased response speed.

Therefore, the rotor 12 can be controlled with high accuracy when it is angularly displaced. The ninth piezoelectric/electrostrictive device 10I is thus suitable for use in controlling an actuator for positional control of a hard disk drive (HDD), controlling the angle of a small reflecting mirror, controlling the rotation of an antenna, controlling the θ-axis of an XY stage, and controlling the rotation of a manipulator.

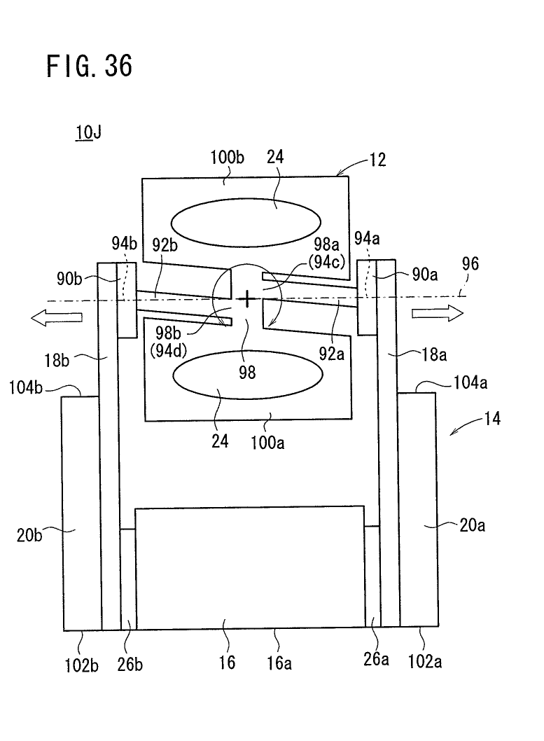

As shown in FIG. 36, a piezoelectric/electrostrictive device 10J according to a tenth embodiment (hereinafter referred to as a tenth piezoelectric/electrostrictive device 10J) of the present invention is of essentially the same structure as the ninth piezoelectric/electrostrictive device 10I described above, but differs therefrom with respect to the structure of the rotor 12, as follows:

The rotor 12 has a constricted portion 98 in a central region in the longitudinal direction thereof, i.e. along the longitudinal direction of the first vibratory plate 18a and the second vibratory plate 18b. Specifically, the rotor 12 has a first wide portion 100a on one side, which is close to the stationary member 16, of the constricted portion 98, and a second wide portion 100b on the other side, which is remote from the stationary member 16, of the constricted portion 98. As with the first piezoelectric/electrostrictive device 10A, a slider, a sensor, a stage, or the like is mounted on the rotor 12. Such a slider, sensor, stage, or the like may be secured to the rotor 12 by an adhesive 24, which is applied to the first wide portion 100a and the second wide portion 100b.

The rotor 12 also has a first connector 92a extending from a first portion 98a, i.e., at a position closer to the second wide portion 100b, of the constricted portion 98, which faces the first vibratory plate 18a, toward the first vibratory plate 18a, and interconnecting the first portion 98a and at least a first thick portion 90a of the first vibratory plate 18a. In addition, the rotor 12 has a second connector 92b extending from a second portion 98b, i.e., at a position closer to the first wide portion 100a, of the constricted portion 98, which faces the second vibratory plate 18b, toward the second vibratory plate 18b, and interconnecting the second portion 98b and at least a second thick portion 90b of the second vibratory plate 18b.

The first connector 92a is of a shape having a cross-sectional area that is substantially uniform from the constricted portion 98 to the first vibratory plate 18a. The first connector 92a may be formed integrally with the constricted portion 98 of the rotor 12, or may be secured to the constricted portion 98 by an adhesive, not shown. Similarly, the first connector 92a may be formed integrally with the first thick portion 90a of the first vibratory plate 18a, or may be secured to the first thick portion 90a by an adhesive, not shown.

The second connector 92b is of a shape having a cross-sectional area that is substantially uniform from the constricted portion 98 to the second vibratory plate 18b. The second connector 92b may be formed integrally with the constricted portion 98 of the rotor 12, or may be secured to the constricted portion 98 by an adhesive, not shown. Similarly, the second connector 92b may be formed integrally with the second thick portion 90b of the second vibratory plate 18b, or may be secured to the second thick portion 90b by an adhesive, not shown.

In the tenth piezoelectric/electrostrictive device 10J, a first joint position 94a between the first connector 92a and the first vibratory plate 18a, and a second joint position 94b between the second connector 92b and the second vibratory plate 18b, are in a substantially confronting positional relationship. The first joint position 94a and the second joint position 94b are formed on a single extension 96, including the center of gravity of the rotor 12, located at the position indicated by “+” in FIG. 36.

A third joint position 94c, between the first portion 98a of the constricted portion 98 and the first connector 92a, and a fourth joint position 94d, between the second portion 98b of the constricted portion 98 and the second connector 92b, are positionally related to each other in point symmetry with respect to the center of gravity of the rotor 12.

With the tenth piezoelectric/electrostrictive device 10J, as with the ninth piezoelectric/electrostrictive device 10, when the first piezoelectric/electrostrictive element 20a actuates the first vibratory plate 18a so as to curve outwardly, and the second piezoelectric/electrostrictive element 20b actuates the second vibratory plate 18b so as to curve outwardly, the rotor 12 is angularly displaced clockwise in FIG. 36.

Conversely, when the first piezoelectric/electrostrictive element 20a actuates the first vibratory plate 18a so as to curve inwardly, and the second piezoelectric/electrostrictive element 20b actuates the second vibratory plate 18b so as to curve inwardly, the rotor 12 is angularly displaced counterclockwise in FIG. 36.

When the first piezoelectric/electrostrictive element 20a actuates the first vibratory plate 18a so as to curve outwardly, and the second piezoelectric/electrostrictive element 20b actuates the second vibratory plate 18b so as to curve inwardly, the rotor 12 is translated to the right in FIG. 36. When the first piezoelectric/electrostrictive element 20a actuates the first vibratory plate 18a so as to curve inwardly, and the second piezoelectric/electrostrictive element 20b actuates the second vibratory plate 18b so as to curve outwardly, the rotor 12 is translated to the left in FIG. 36.

As with the ninth piezoelectric/electrostrictive device 10, when the rotor 12 or an object to which the rotor 12 is fixed is angularly displaced, because movement of the center of gravity of the rotor 12 is small, reactive forces generated in a region (i.e., a region of the stationary member 16) at which the tenth piezoelectric/electrostrictive device 10J is fixed in place are small, and thus the tenth piezoelectric/electrostrictive device 10J can actuate the object under an easy control with an increased actuating frequency and an increased response speed.

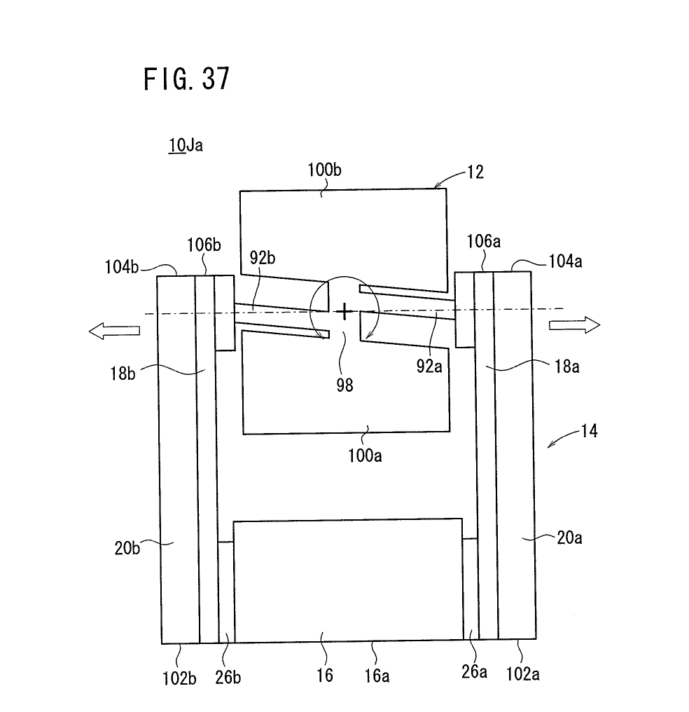

In the embodiment shown in FIG. 36, the first piezoelectric/electrostrictive element 20a and the second piezoelectric/electrostrictive element 20b have respective end faces 102a, 102b substantially aligned with an end face, i.e., a lower end 16a, of the stationary member 16, and have respective other end faces 104a, 104b displaced from the first thick portion 90a and the second thick portion 90b toward the stationary member 16. FIG. 37 shows a piezoelectric/electrostrictive device 10Ja according to a first modification. In the piezoelectric/electrostrictive device 10Ja according to the first modification, the respective other end faces 104a, 104b of the first piezoelectric/electrostrictive element 20a and the second piezoelectric/electrostrictive element 20b are positionally aligned with or positioned close to respective distal end faces 106a, 106b of the first vibratory plate 18a and the second vibratory plate 18b.

Since the first vibratory plate 18a and the second vibratory plate 18b have increased rigidity in this case, they are less susceptible to external forces, such as external air pressure, and hence are less liable to cause the rotor 12 to vibrate unnecessarily.

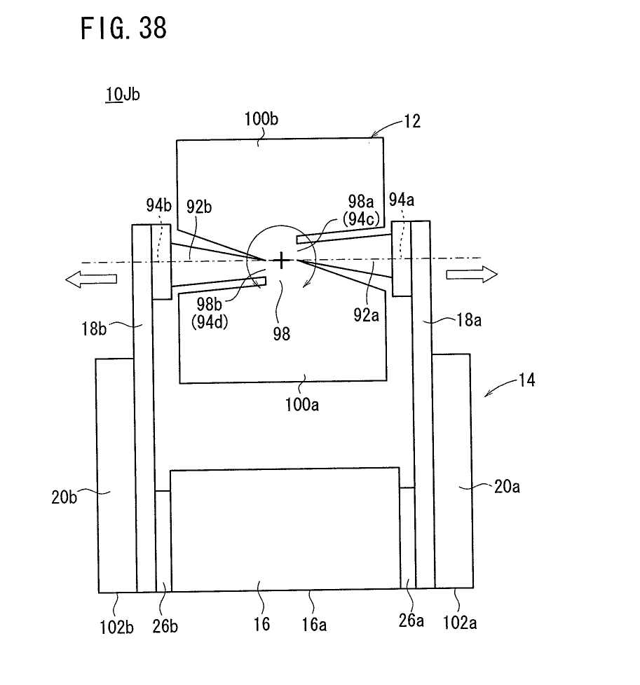

In the embodiment shown in FIG. 36, the first connector 92a is of a shape having a cross-sectional area that is substantially uniform from the constricted portion 98 to the first vibratory plate 18a, and the second connector 92b is of a shape having a cross-sectional area that is substantially uniform from the constricted portion 98 to the second vibratory plate 18b. FIG. 38 shows a piezoelectric/electrostrictive device 10Jb according to a second modification. In the piezoelectric/electrostrictive device 10Jb according to the second modification, the first connector 92a is of a shape having a cross-sectional area that is progressively greater from the constricted portion 98 to the first vibratory plate 18a, and the second connector 92b is of a shape having a cross-sectional area that is progressively greater from the constricted portion 98 to the second vibratory plate 18b. Alternatively, although not shown, the first connector 92a may be of a shape having a cross-sectional area that is progressively smaller from the constricted portion 98 to the first vibratory plate 18a, and the second connector 92b may be of a shape having a cross-sectional area that is progressively smaller from the constricted portion 98 to the second vibratory plate 18b.

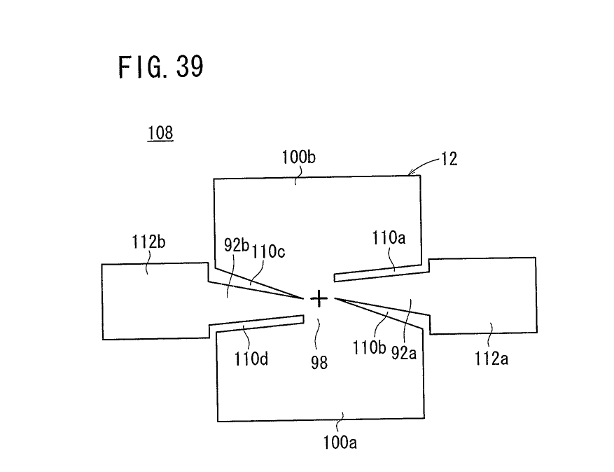

Two methods of manufacturing the piezoelectric/electrostrictive device 10Jb according to the second modification shall be described below with reference to FIGS. 39 through 45.

According to the first manufacturing method, as shown in FIG. 39, a single metal plate 108 is prepared. Then, the metal plate 108 is punched to form twenty-first through twenty-fourth slots 110a through 100d, thereby fabricating the rotor 12 having the constricted portion 98, the first wide portion 100a, the second wide portion 100b, the first connector 92a, and the second connector 92b. The constricted portion 98, the first connector 92a, and the second connector 92b are formed integrally with each other. A first stiffener 112a extending outwardly from the first connector 92a and a second stiffener 112b extending outwardly from the second connector 92b may also be formed simultaneously.

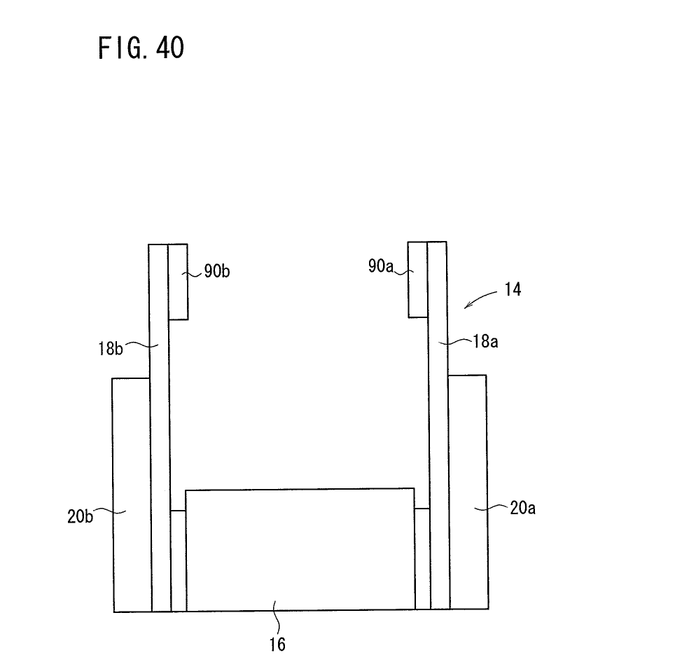

As shown in FIG. 40, the rotary actuator 14 for angularly displacing the rotor 12 is fabricated by integrally sintering a laminated assembly of ceramic green sheets.

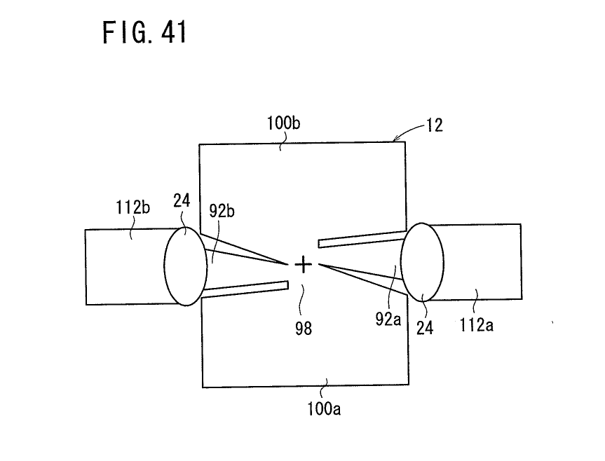

Thereafter, as shown in FIG. 41, an end of the first connector 92a, i.e., a portion between the first connector 92a and the first stiffener 112a, and an end of the second connector 92b, i.e., a portion between the second connector 92b and the second stiffener 112b, are coated with an adhesive 24, which may comprise an ultraviolet-curable resin, an epoxy resin, or the like.

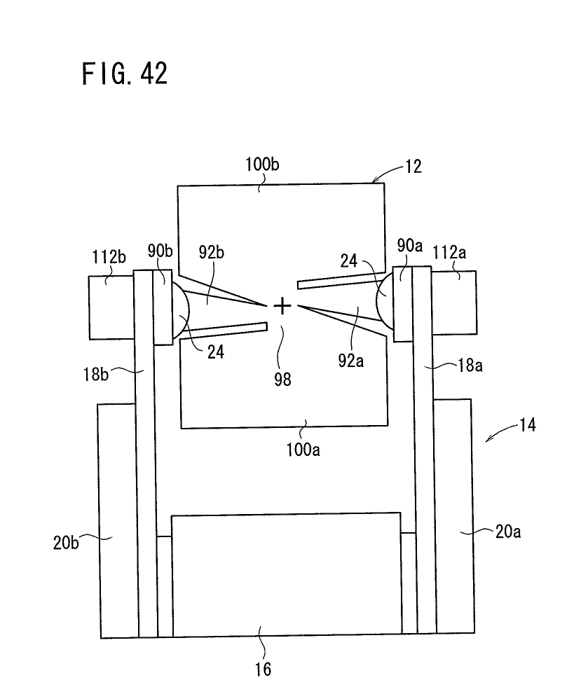

Thereafter, as shown in FIG. 42, the first connector 92a of the rotor 12 and the first vibratory plate 18a of the rotary actuator 14 are secured to each other by the adhesive 24. In addition, the second connector 92b of the rotor 12 and the second vibratory plate 18b of the rotary actuator 14 are secured to each other by the adhesive 24. The end of the first connector 92a, which is coated with the adhesive 24, and a side surface of the first thick portion 90a, e.g., a rear end face thereof, are secured to each other by the adhesive 24. Further, the end of the second connector 92b, which is coated with the adhesive 24, and a side surface of the second thick portion 90b, e.g., a rear end face thereof, are secured to each other by the adhesive 24. At this time, the first stiffener 112a may be bent and bonded to the first vibratory plate 18a in order to increase the rigidity of the first vibratory plate 18a. Likewise, the second stiffener 112b may be bent and bonded to the second vibratory plate 18b in order to increase the rigidity of the second vibratory plate 18b.

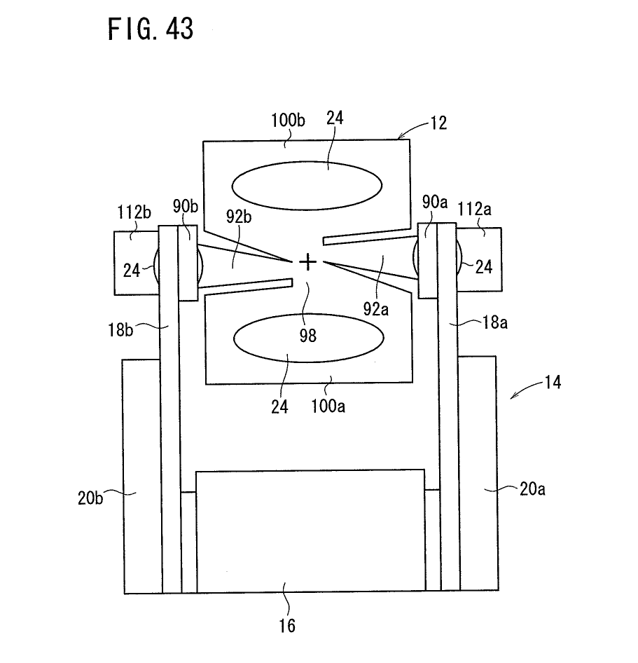

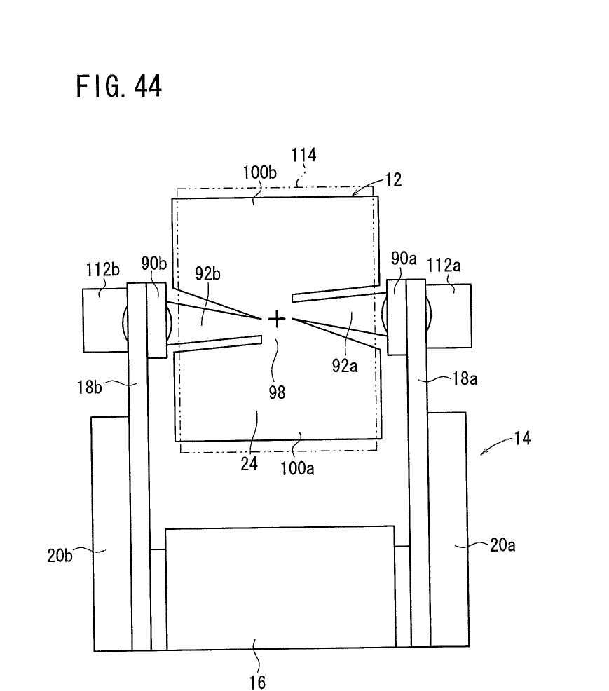

Thereafter, as shown in FIG. 43, each of the first wide portion 100a and the second wide portion 100b of the rotor 12 is coated with an adhesive 24, which is used to secure a component 114 such as a slider, a sensor, a stage, or the like (indicated by the two-dot-and-dash lines in FIG. 44) to the rotor 12.

Then, as shown in FIG. 44, the component 114 is secured to the first wide portion 100a and to the second wide portion 100b of the rotor 12 by the adhesive 24, thus completing the piezoelectric/electrostrictive device 10Jb according to the second modification.

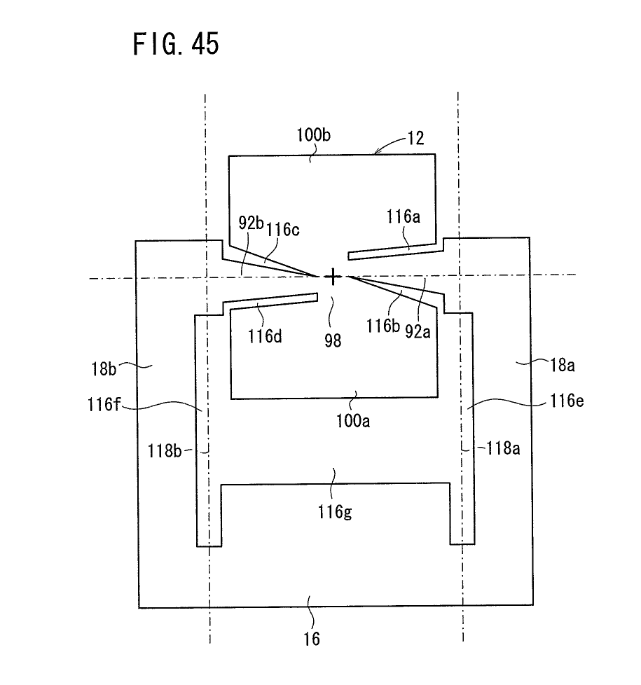

According to the second manufacturing method, as shown in FIG. 45, a single metal plate 108 is prepared. Then, the metal plate 108 is punched to form thirty-first through thirty-seventh slots 116a through 116g, thereby shaping the rotor 12, the constricted portion 98 of the rotor 12, the first wide portion 100a, the second wide portion 100b, the first connector 92a, the second connector 92b, the first vibratory plate 18a, the second vibratory plate 18b, and the stationary member 16 of the rotary actuator 14.

Thereafter, the first vibratory plate 18a and the second vibratory plate 18b are bent respectively about a straight portion of the thirty-fifth slot 116e along the first vibratory plate 18a as a thirty-first fold line, and about a straight portion of the thirty-sixth slot 116f along the second vibratory plate 18b as a thirty-second fold line.

Thereafter, the first piezoelectric/electrostrictive element 20a is secured to a side surface of the first vibratory plate 18a by an adhesive, for example. In addition, the second piezoelectric/electrostrictive element 20b is secured to a side surface of the second vibratory plate 18b by an adhesive, for example.

Then, the component 114, not shown, is secured to the rotor 12 by an adhesive, thereby completing the modified piezoelectric/electrostrictive device 10Jb.

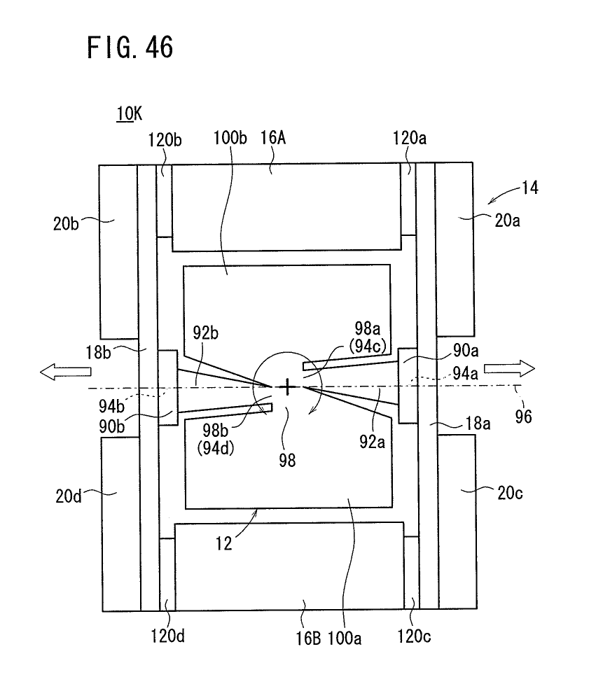

As shown in FIG. 46, a piezoelectric/electrostrictive device 10K according to an eleventh embodiment of the present invention (hereinafter referred to as an eleventh piezoelectric/electrostrictive device 10K) is of essentially the same structure as the piezoelectric/electrostrictive device 10Jb according to the second modification described above, but differs therefrom as follows:

The rotary actuator 14 is in the form of a frame comprising a first vibratory plate 18a, a second vibratory plate 18b, a first stationary member 16A, and a second stationary member 16B.

A first thick portion 90a is disposed on a longitudinally central portion of an inner side surface of the first vibratory plate 18a that faces the second vibratory plate 18b, and a second thick portion 90b is disposed on a longitudinally central portion of an inner side surface of the second vibratory plate 18b that faces the first vibratory plate 18a.

The first stationary member 16A and the second stationary member 16B are spaced from each other. The first stationary member 16A is fixed in place between a surface of a distal end of the first vibratory plate 18a that faces the second vibratory plate 18b and a surface of a distal end of the second vibratory plate 18b that faces the first vibratory plate 18a. The second stationary member 16B is fixed in place between a surface of another distal end of the first vibratory plate 18a that faces the second vibratory plate 18b and a surface of another distal end of the second vibratory plate 18b that faces the first vibratory plate 18a.

An eleventh plate member 120a and a twelfth plate member 120b used for positioning are interposed between the first stationary member 16A and the first vibratory plate 18a, and between the first stationary member 16A and the second vibratory plate 18b. A thirteenth plate member 120c and a fourteenth plate member 120d are interposed between the second stationary member 16B and the first vibratory plate 18a, and between the second stationary member 16B and the second vibratory plate 18b.

A first piezoelectric/electrostrictive element 20a is mounted on a side surface of the first vibratory plate 18a and extends from a position corresponding to an end face of the first stationary member 16A to a position displaced from the first thick portion 90a toward the first stationary member 16A. A second piezoelectric/electrostrictive element 20b is mounted on a side surface of the second vibratory plate 18b and extends from a position corresponding to an end face of the first stationary member 16A to a position displaced from the second thick portion 90b toward the first stationary member 16A.

Similarly, a third piezoelectric/electrostrictive element 20c is mounted on a side surface of the first vibratory plate 18a, and extends from a position corresponding to an end face of the second stationary member 16B to a position displaced from the first thick portion 90a toward the second stationary member 16B, whereas a fourth piezoelectric/electrostrictive element 20d is mounted on a side surface of the second vibratory plate 18b, and extends from a position corresponding to an end face of the second stationary member 16B to a position displaced from the second thick portion 90b toward the second stationary member 16B.

A first connector 92a extends from a first portion 98a, which faces the first vibratory plate 18a and is close to a second wide portion 100b, of a constricted portion 98 of the rotor 12 toward the first vibratory plate 18a, and has one end fixed thereof to the first thick portion 90a of the first vibratory plate 18a. A second connector 92b extends from a second portion 98b, which faces the first vibratory plate 18a and is close to a first wide portion 100a, of the constricted portion 98 toward the second vibratory plate 18b, and has one end thereof fixed to the second thick portion 90b of the second vibratory plate 18b.

When the first piezoelectric/electrostrictive element 20a and the third piezoelectric/electrostrictive element 20c actuate the first vibratory plate 18a so as to curve outwardly, and the second piezoelectric/electrostrictive element 20b and the fourth piezoelectric/electrostrictive element 20d actuate the second vibratory plate 18b so as to curve outwardly, the rotor 12 is angularly displaced clockwise in FIG. 46.

Conversely, when the first piezoelectric/electrostrictive element 20a and the third piezoelectric/electrostrictive element 20c actuate the first vibratory plate 18a so as to curve inwardly, and the second piezoelectric/electrostrictive element 20b and the fourth piezoelectric/electrostrictive element 20d actuate the second vibratory plate 18b so as to curve inwardly, the rotor 12 is angularly displaced counterclockwise in FIG. 46.

In the eleventh piezoelectric/electrostrictive device 10K, as with the tenth piezoelectric/electrostrictive device 10J, therefore, when the rotor 12 and an object to which the rotor 12 is connected are angularly displaced, any movement of the center of gravity of the rotor 12 is small. Therefore, reactive forces generated in a region (i.e., a region of the first stationary member 16A and the second stationary member 16B) at which the eleventh piezoelectric/electrostrictive device 10K is fixed in place are small, and the eleventh piezoelectric/electrostrictive device 10K can actuate the rotor 12 and the object under an easy control with an increased actuating frequency and an increased response speed.

In the eleventh piezoelectric/electrostrictive device 10K, the first stationary member 16A and the second stationary member 16B may each be secured to different members. However, since the overall lengths of the first vibratory plate 18a and the second vibratory plate 18b vary when the first vibratory plate 18a and the second vibratory plate 18b are deformed by the first through fourth piezoelectric/electrostrictive members 20a through 20d, if the first stationary member 16A and the second stationary member 16B are secured to different members, then the angular displacement of the rotor 12 may possibly be obstructed. It is thus preferable to fix only the second stationary member 16B, for example, to another member and to keep the first stationary member 16A in an unfixed state.

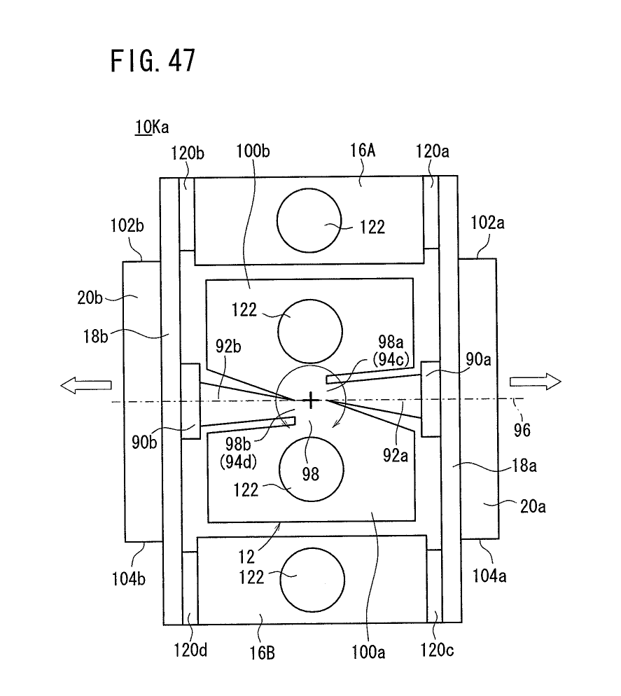

In the above embodiment, the first piezoelectric/electrostrictive element 20a and the third piezoelectric/electrostrictive element 20c are mounted on the first vibratory plate 18a, whereas the second piezoelectric/electrostrictive element 20b and the fourth piezoelectric/electrostrictive element 20d are mounted on the second vibratory plate 18b. FIG. 47 shows a piezoelectric/electrostrictive element 10Ka according to a modification thereof. In the piezoelectric/electrostrictive element 10Ka, the first piezoelectric/electrostrictive element 20a is mounted on a longitudinally central portion of a side surface of the first vibratory plate 18a, and the second piezoelectric/electrostrictive element 20b is mounted on a longitudinally central portion of a side surface of the second vibratory plate 18b.

The first piezoelectric/electrostrictive element 20a has one end face 102a disposed in a position short of the joint between the first vibratory plate 18a and the first stationary member 16A, and an opposite end face 104a thereof disposed in a position short of the joint between the first vibratory plate 18a and the second stationary member 16B.

Similarly, the second piezoelectric/electrostrictive element 20b has one end face 102b disposed in a position short of the joint between the second vibratory plate 18b and the first stationary member 16A, and an opposite end face 104b thereof disposed in a position short of the joint between the second vibratory plate 18b and the second stationary member 16B.

When the first piezoelectric/electrostrictive element 20a actuates the first vibratory plate 18a so as to curve outwardly, and the second piezoelectric/electrostrictive element 20b actuates the second vibratory plate 18b so as to curve outwardly, the rotor 12 is displaced angularly clockwise in FIG. 47.

Conversely, when the first piezoelectric/electrostrictive element 20a actuates the first vibratory plate 18a so as to curve inwardly, and the second piezoelectric/electrostrictive element 20b actuates the second vibratory plate 18b so as to curve inwardly, the rotor 12 is displaced angularly counterclockwise in FIG. 47.

As typically shown in FIG. 47, the first wide portion 100a, the second wide portion 100b, the first stationary member 16A, and the second stationary member 16B of the rotor 12 may have holes 122 provided therein, such as holes for applying an adhesive, reference holes for use in assembling parts, screw holes, mounting holes, holes for weight reduction, or the like.

Although certain preferred embodiments of the present invention have been shown and described in detail, it should be understood that various changes and modifications may be made to such embodiments without departing from the scope of the invention as set forth in the appended claims.

What is claimed is:

1. A piezoelectric/electrostrictive device comprising:
a rotor; and
a rotary actuator for angularly displacing said rotor;
said rotary actuator having a stationary member, with a first vibratory plate and a second vibratory plate extending in one direction from opposite sides of said stationary member, and a piezoelectric/electrostrictive element mounted on at least one of said first and second vibratory plates for actuating said at least one of said first and second vibratory plates; and
said rotor having a pair of opposite surfaces, one of said opposite surfaces including a first end secured to said first vibratory plate, and the other of said opposite surfaces having a second end, which is diagonally opposite to said first end, secured to said second vibratory plate.

2. A piezoelectric/electrostrictive device according to claim 1, wherein the distance between said first end of said rotor that is secured to said first vibratory plate and a boundary region between said first vibratory plate and said stationary member is represented by L1, and the distance between said second end of said rotor that is secured to said second vibratory plate and a boundary region between said second vibratory plate and said stationary member is represented by L2, wherein said distance L1 and said distance L2 satisfy the relationship L1=L2.

3. A piezoelectric/electrostrictive device comprising:
a rotor; and
a rotary actuator for angularly displacing said rotor;
said rotary actuator having a first stationary member and a second stationary member which are spaced from each other, a first vibratory plate extending in one direction from one side of said first stationary member, a second vibratory plate extending in one direction from one side of said second stationary member, and a piezoelectric/electrostrictive element mounted on at least one of said first and second vibratory plates for actuating said at least one of said first and second vibratory plates; and
said rotor having a pair of opposite surfaces, one of said opposite surfaces including a first end secured to said first vibratory plate, and the other of said opposite surfaces having a second end, which is diagonally opposite to said first end, secured to said second vibratory plate.

4. A piezoelectric/electrostrictive device according to claim 3, wherein said first vibratory plate has a first protrusion mounted on a surface thereof which faces said one surface of said rotor;
said second vibratory plate has a second protrusion mounted on a surface thereof which faces said other surface of said rotor;
said first protrusion and said one surface of said rotor are secured to each other; and
said second protrusion and said other surface of said rotor are secured to each other.

5. A piezoelectric/electrostrictive device according to claim 3, wherein said first stationary member has a third protrusion mounted on a surface thereof which faces said rotor;
said second stationary member has a fourth protrusion mounted on a surface thereof which faces said rotor;
said third protrusion and said rotor are secured to each other; and
said fourth protrusion and said rotor are secured to each other.

6. A piezoelectric/electrostrictive device comprising:
a rotor; and
a rotary actuator for angularly displacing said rotor;
said rotary actuator having a central member extending in a first direction, a first arm extending from a first end of said central member in a second direction, a second arm extending from a second end of said central member in a third direction which is opposite to said second direction, a first vibratory plate extending from an end of said first arm in said first direction, a third arm extending from an end of said first vibratory plate in said third direction, a second vibratory plate extending from an end of said second arm in said first direction, a fourth arm extending from an end of said second vibratory plate in said second direction, and a piezoelectric/electrostrictive element mounted on at least one of said first and second vibratory plates for actuating said at least one of said first and second vibratory plates.

7. A piezoelectric/electrostrictive device according to claim 6, wherein said central member comprises a stationary member; and
said rotor has, on a principal surface thereof, a first corner secured to said third arm and a second corner, which is diagonally opposite to said first corner, secured to said fourth arm.

8. A piezoelectric/electrostrictive device according to claim 6, wherein each of said third arm and said fourth arm comprises a stationary member; and
said rotor is secured to said central member.

9. A piezoelectric/electrostrictive device comprising:
a rotor; and
a rotary actuator for angularly displacing said rotor;
said rotary actuator having a first stationary member and a second stationary member which are spaced from each other, a central member disposed between said first stationary member and said second stationary member and extending in a first direction, a first vibratory plate extending from a first end of said first stationary member toward said second stationary member, a second vibratory plate extending from a second end, which is diagonally opposite to said first end, of said second stationary member toward said first stationary member, a first displacement transmitter connected between a third end, which is closer to said first stationary member, of said central member on a surface thereof which faces said first vibratory plate, and an end of said first vibratory plate, for transmitting displacement of said first vibratory plate to said central member, a second displacement transmitter connected between a fourth end, which is closer to said second stationary member, of said central member on a surface thereof which faces said second vibratory plate, and an end of said second vibratory plate, for transmitting displacement of said second vibratory plate to said central member, and a piezoelectric/electrostrictive element mounted on at least one of said first and second vibratory plates for actuating said at least one of said first and second vibratory plates; and
said rotor being secured to said central member.

10. A piezoelectric/electrostrictive device comprising:
a rotor; and
a rotary actuator for angularly displacing said rotor;
said rotary actuator having a first stationary member and a second stationary member which are spaced from each other, a first metal vibratory plate extending from said first stationary member toward said second stationary member, a second metal vibratory plate extending from said second stationary member toward said first stationary member, and a piezoelectric/electrostrictive element mounted on at least one of said first and second vibratory plates for actuating said at least one of said first and second vibratory plates; and
said rotor having a pair of opposite surfaces, one of said opposite surfaces having a first end secured to said first vibratory plate, and the other of said opposite surfaces having a second end, which is diagonally opposite to said first end, secured to said second vibratory plate.

11. A piezoelectric/electrostrictive device according to claim 10, wherein said first stationary member and said second stationary member are integrally combined with each other by a frame.

12. A piezoelectric/electrostrictive device according to claim 10, wherein said first stationary member, said first vibratory plate, said second stationary member, and said second vibratory plate are formed by punching and bending a single metal plate.

13. A piezoelectric/electrostrictive device comprising:
a rotor; and
a rotary actuator for angularly displacing said rotor;
said rotary actuator having a first stationary member and a second stationary member which are spaced from each other, a first metal vibratory plate extending from said first stationary member toward said second stationary member, a second metal vibratory plate extending from said second stationary member toward said first stationary member, a rotor mount secured to an end of said first vibratory plate and to an end of said second vibratory plate, and a piezoelectric/electrostrictive element mounted on at least one of said first and second vibratory plates for actuating said at least one of said first and second vibratory plates; and
said rotor being mounted on said rotor mount.

14. A piezoelectric/electrostrictive device according to claim 13, wherein said first stationary member and said second stationary member are integrally combined with each other by a frame.

15. A piezoelectric/electrostrictive device according to claim 13, wherein said first stationary member, said first vibratory plate, said second stationary member, said second vibratory plate, and said rotor mount are formed by punching and bending a single metal plate.

16. A piezoelectric/electrostrictive device comprising:
a rotor; and
a rotary actuator for angularly displacing said rotor;
said rotary actuator having a stationary member, a first metal vibratory plate having an end secured to said stationary member and extending in one direction, a second metal vibratory plate having an end secured to said stationary member and extending along an extension of said first vibratory plate, a third metal vibratory plate having an end secured to said stationary member, said third vibratory plate being spaced from said first vibratory plate and extending substantially parallel thereto, a fourth metal vibratory plate having an end secured to said stationary member and extending along an extension of said third vibratory plate, and a piezoelectric/electrostrictive element mounted on at least one of said first through fourth vibratory plates for actuating said at least one of said first through fourth vibratory plates; and
said rotor having a pair of opposite surfaces, one of said opposite surfaces having a first end secured to said first vibratory plate, and the other of said opposite surfaces having a second end, which is diagonally opposite to said first end, secured to said fourth vibratory plate.

17. A piezoelectric/electrostrictive device according to claim 16, wherein said stationary member comprises a frame;
said first vibratory plate and said second vibratory plate are secured to a first arm extending from one of two opposite surfaces of said frame to the other surface thereof; and
said third vibratory plate and said fourth vibratory plate are secured to a second arm extending from said other surface of said frame to said one surface thereof.

18. A piezoelectric/electrostrictive device according to claim 16, wherein said stationary member has a rectangular planar shape;
said first vibratory plate and said second vibratory plate are secured to a first arm extending upwardly from one of two opposite surfaces of said stationary member; and
said third vibratory plate and said fourth vibratory plate are secured to a second arm extending upwardly from the other of said two opposite surfaces of said stationary member.

19. A piezoelectric/electrostrictive device according to claim 16, wherein said stationary member and said first through fourth vibratory plates are formed by punching and bending a single metal plate.

20. A piezoelectric/electrostrictive device according to claim 16, wherein those of said first through fourth vibratory plates which are free of said piezoelectric/electrostrictive element comprise a spring.

21. A piezoelectric/electrostrictive device comprising:
a rotor; and
a rotary actuator for angularly displacing said rotor;
said rotary actuator having a stationary member, a first metal vibratory plate having an end secured to said stationary member and extending in one direction, a second metal vibratory plate having an end secured to said stationary member and extending along an extension of said first vibratory plate, a third metal vibratory plate having an end secured to said stationary member, said third vibratory plate being spaced from said first vibratory plate and extending substantially parallel thereto, a fourth metal vibratory plate having an end secured to said stationary member and extending along an extension of said third vibratory plate, a rotor mount secured to respective ends of said first through fourth vibratory plates, and a piezoelectric/electrostrictive element mounted on at least one of said first through fourth vibratory plates for actuating said at least one of said first through fourth vibratory plates; and
said rotor being mounted on said rotor mount.

22. A piezoelectric/electrostrictive device according to claim 21, wherein said stationary member comprises a frame;
said first vibratory plate and said second vibratory plate are secured to a first arm extending from one of two opposite surfaces of said frame to the other surface thereof; and
said third vibratory plate and said fourth vibratory plate are secured to a second arm extending from said other surface of said frame to said one surface thereof.

23. A piezoelectric/electrostrictive device according to claim 21, wherein said stationary member has a rectangular planar shape;
said first vibratory plate and said second vibratory plate are secured to a first arm extending upwardly from one of two opposite surfaces of said stationary member; and
said third vibratory plate and said fourth vibratory plate are secured to a second arm extending upwardly from the other of said two opposite surfaces of said stationary member.

24. A piezoelectric/electrostrictive device according to claim 21, wherein said rotor mount comprises a plurality of feet fixed to respective ends of said first through fourth vibratory plates.

25. A piezoelectric/electrostrictive device according to claim 21, wherein said stationary member, said first through fourth vibratory plates, and said rotor mount are formed by punching and bending a single metal plate.

26. A piezoelectric/electrostrictive device according to claim 21, wherein those of said first through fourth vibratory plates which are free of said piezoelectric/electrostrictive element comprise a spring.

27. A piezoelectric/electrostrictive device comprising:
a rotor; and
a rotary actuator for angularly displacing said rotor;
said rotary actuator having a stationary member, with a first vibratory plate and a second vibratory plate having respective ends secured to said stationary member and which are angularly spaced from each other by a predetermined angle, a movable member connected between another end of said first vibratory plate and another end of said second vibratory plate, and a piezoelectric/electrostrictive element mounted on at least one of said first and second vibratory plates for actuating said at least one of said first and second vibratory plates; and
said rotor being secured to said movable member.

28. A piezoelectric/electrostrictive device according to claim 27, wherein said predetermined angle comprises an acute angle.

29. A piezoelectric/electrostrictive device according to claim 27, wherein said predetermined angle comprises an obtuse angle.

30. A piezoelectric/electrostrictive device according to claim 27, wherein said predetermined angle is 90 degrees.

31. A piezoelectric/electrostrictive device according to claim 27, wherein said predetermined angle is 180 degrees.

32. A piezoelectric/electrostrictive device comprising:
a rotor; and
a rotary actuator for angularly displacing said rotor;
said rotary actuator having a stationary member, with a first vibratory plate and a second vibratory plate extending in one direction from opposite sides of said stationary member, and a piezoelectric/electrostrictive element mounted on at least one of said first and second vibratory plates for actuating said at least one of said first and second vibratory plates; and
said rotor having a first connector extending from a first portion thereof, which faces said first vibratory plate, to said first vibratory plate, said first connector interconnecting said first portion and said first vibratory plate, and a second connector extending from a second portion thereof, which faces said second vibratory plate, to said second vibratory plate, said second connector interconnecting said second portion and said second vibratory plate.

33. A piezoelectric/electrostrictive device according to claim 32, wherein said rotor has a constricted portion;
said first portion is positioned on said constricted portion, which faces said first vibratory plate; and
said second portion is positioned on said constricted portion, which faces said second vibratory plate.

34. A piezoelectric/electrostrictive device according to claim 33, wherein said first connector is of a shape having a cross-sectional area that is substantially uniform from said constricted portion to said first vibratory plate; and
said second connector is of a shape having a cross-sectional area that is substantially uniform from said constricted portion to said second vibratory plate.

35. A piezoelectric/electrostrictive device according to claim 33, wherein said first connector is of a shape having a cross-sectional area that progressively varies from said constricted portion to said first vibratory plate; and
said second connector is of a shape having a cross-sectional area that progressively varies from said constricted portion to said second vibratory plate.

36. A piezoelectric/electrostrictive device according to claim 32, wherein said first connector and said first vibratory plate are secured to each other by an adhesive; and
said second connector and said second vibratory plate are secured to each other by an adhesive.

37. A piezoelectric/electrostrictive device according to claim 32, wherein said first connector and said second connector are formed integrally with said rotor, said first vibratory plate, and said second vibratory plate by punching and bending a metal plate.

38. A piezoelectric/electrostrictive device according to claim 32, wherein a first joint position between said first connector and said first vibratory plate, and a second joint position between said second connector and said second vibratory plate, are in a substantially confronting positional relationship.

39. A piezoelectric/electrostrictive device according to claim 32, wherein a third joint position between said first portion of said rotor and said first connector, and a fourth joint position between said second portion of said rotor and said second connector, are positionally related to each other in point symmetry with respect to a center of gravity of said rotor.
